(19) United States
(12) Patent Application Publication
(10) Pub. No.: US 2024/0169111 A1
(43) Pub. Date: May 23, 2024

(54) PARAMETERIZING HOT STARTS TO MAXIMIZE TEST REPEATABILITY

(71) Applicant: GM Cruise Holdings LLC, San Francisco, CA (US)

(72) Inventors: Joseph Gribble, Kirkland, WA (US); Sagar Tatipamula, Mountain View, CA (US); Matthew Kowalski, Yorktown, VA (US); Yeshaswi Laxman Menghmalani, Milpitas, CA (US); Alessandro Iyra, Oakland, CA (US)

(21) Appl. No.: 17/990,430

(22) Filed: Nov. 18, 2022

(51) Int. Cl. G06F 30/20; G06F 11/36

(52) U.S. Cl. CPC G06F 30/20; G06F 11/3664

(57) ABSTRACT

Systems and techniques are provided for testing software. A method can generate, based on sensor data reflecting a pose/behavior of an autonomous vehicle (AV) during an event, a simulation of a trip by the AV comprising an evaluation window for testing a simulated pose/behavior of the AV after a software modification; iteratively adjust the time interval to yield an evaluation window for each iteration of adjustments to the time interval, each evaluation window including a time interval including the event and an evaluation start and end; select one of the evaluation windows based on a comparison of AV metrics from each respective simulation of the AV during the evaluation windows and divergences in an AV pose/behavior during each evaluation window and a pose/behavior of the AV during the trip; simulate a pose/behavior of the AV during the evaluation window; and simulate a performance of the AV during the evaluation window.

### TECHNICAL FIELD

The present disclosure generally relates to testing software of autonomous vehicles. For example, aspects of the present disclosure relate to systems and techniques for parameterizing hot starts to maximize repeatability of software tests and simulation frameworks.

### BACKGROUND

An autonomous vehicle is a motorized vehicle that can navigate without a human driver. An exemplary autonomous vehicle can include various sensors, such as a camera sensor, a light detection and ranging (LIDAR) sensor, and a radio detection and ranging (RADAR) sensor, amongst others. The sensors collect data and measurements that the autonomous vehicle can use for operations such as navigation. The sensors can provide the data and measurements to an internal computing system of the autonomous vehicle, which can use the data and measurements to control a mechanical system of the autonomous vehicle, such as a vehicle propulsion system, a braking system, or a steering system. Typically, the sensors are mounted at specific locations on the autonomous vehicles.

### BRIEF DESCRIPTION OF THE DRAWINGS

Illustrative examples and aspects of the present application are described in detail below with reference to the following figures:

FIG. 1 is a diagram illustrating an example system environment that can be used to facilitate autonomous vehicle (AV) navigation and routing operations, in accordance with some examples of the present disclosure;

FIG. 2 is a diagram illustrating an example simulation framework, in accordance with some examples of the present disclosure;

FIG. 3 is a diagram illustrating an example simulation segment, in accordance with some examples of the present disclosure;

FIGS. 4A through 4C are diagrams illustrating various example simulation segments generated by an example simulator at various iterations implemented to determine a particular evaluation window that ensures or provides an increased or maximum test repeatability for simulating and testing a behavior of an autonomous vehicle when encountering a particular event, in accordance with some examples of the present disclosure;

FIG. 5A is a diagram illustrating an example simulation showing a divergence between a simulation path and an actual road data path, in accordance with some examples of the present disclosure;

FIG. 5B is a diagram illustrating another example simulation showing a divergence between a simulation path and an actual real-world path of an autonomous vehicle, in accordance with some examples of the present disclosure;

FIG. 6 is a flowchart illustrating an example process for running simulation tests and maximizing a repeatability of the simulation tests, in accordance with some examples of the present disclosure; and

FIG. 7 is a diagram illustrating an example system architecture for implementing certain aspects described herein.

### DETAILED DESCRIPTION

Certain aspects and examples of this disclosure are provided below. Some of these aspects and examples may be applied independently and some of them may be applied in combination as would be apparent to those of skill in the art. In the following description, for the purposes of explanation, specific details are set forth in order to provide a thorough understanding of aspects and examples of the application. However, it will be apparent that various aspects and examples may be practiced without these specific details. The figures and description are not intended to be restrictive.

The ensuing description provides aspects and examples of the disclosure, and is not intended to limit the scope, applicability, or configuration of the disclosure. Rather, the ensuing description of the aspects and examples of the disclosure will provide those skilled in the art with an enabling description for implementing an example implementation of the disclosure. It should be understood that various changes may be made in the function and arrangement of elements without departing from the scope of the application as set forth in the appended claims.

One aspect of the present technology is the gathering and use of data available from various sources to improve quality and experience. The present disclosure contemplates that in some instances, this gathered data may include personal information. The present disclosure contemplates that the entities involved with such personal information respect and value privacy policies and practices.

As previously explained, autonomous vehicles (AVs) can include various sensors, such as a camera sensor, a light detection and ranging (LIDAR) sensor, a radio detection and ranging (RADAR) sensor, an inertial measurement unit (IMU), and/or an acoustic sensor (e.g., sound navigation and ranging (SONAR), microphone, etc.), global navigation satellite system (GNSS) and/or global positioning system (GPS) receiver, amongst others. The AVs can use the various sensors to collect data and measurements that the AVs can use for AV operations such as perception (e.g., object detection, event detection, tracking, localization, sensor fusion, point cloud processing, image processing, etc.), planning (e.g., route planning, trajectory planning, situation analysis, behavioral and/or action planning, mission planning, etc.), control (e.g., steering, braking, throttling, lateral control, longitudinal control, model predictive control (MPC), proportional-derivative-integral, etc.), prediction (e.g., motion prediction, behavior prediction, etc.), etc. The sensors can provide the data and measurements to an internal computing system of the autonomous vehicle, which can use the data and measurements to control a mechanical system of the autonomous vehicle, such as a vehicle propulsion system, a braking system, and/or a steering system, for example.

The AV software is generally constructed using frameworks/platforms such as, for example, a robot operating system (ROS), which include software stacks configured to perform certain AV operations, process sensor data in a certain way, implement one or more functions/tasks, and/or implement certain AV behaviors. The software stacks can include software nodes configured to generate certain outputs (e.g., perform certain functions/tasks and generate associated outputs). In some examples, a node can include and/or represent a process running on the ROS of an AV. The process can be part of a number of processes associated with an AV stack including the node. One or more of the software nodes may be configured to communicate (e.g., via messages and/or publish/subscribe models) respective outputs to other software nodes configured to generate additional outputs at least partly based on the respective outputs of the one or more software nodes.

For example, nodes can take actions based on information received from other nodes, send information to other nodes, and/or send and receive requests for actions to and from other nodes. Typically, the nodes in the AV software (e.g., in the ROS) may communicate with each other based on contracts. The contracts can define what nodes communicate with what nodes, which nodes are provider nodes (e.g., sender) and which nodes are consumer nodes (e.g., recipient) in specific node communications, what data is communicated between specific nodes, the format of messages communicated between nodes, node dependencies (e.g., what information a node may expect/require from another node), and/or other aspects of node behaviors and/or communications.

In many cases, the AV software (e.g., the ROS) may include AV stacks that have a number of nodes. Software developers may frequently update and/or modify the AV software (e.g., the AV stacks) in order to, for example and without limitation, modify one or more AV behaviors, implement new AV tasks and/or behaviors, correct issues in the code, modify and/or implement certain parameters, and/or modify one or more AV capabilities. Given the frequency of changes made to the AV software, software developers may run a large number of tests to test and/or validate the AV software and/or code changes, identify any issues in the AV software, and/or troubleshoot any errors in the AV software. However, the large number of nodes and the complexity of the AV stacks can make it very difficult for developers to test and troubleshoot the AV software and/or code changes. Moreover, AV stacks and nodes are often developed and/or maintained by different people and/or teams. As a result, it can be difficult for developers to track the changes to AV stacks and/or nodes made by other developers and/or teams.

In addition, when a person or team makes a change to a configuration/behavior of a node and/or AV stack, such change can impact other nodes and/or AV stacks, which in some cases may be managed by other developers or teams. This can make it difficult to identify the impact of a specific change in the code. Moreover, the frequency of code changes in AV software and the impact of a change to a configuration/behavior of a node and/or AV stack (and thus the impact of a code change) can also make it difficult to identify the cause of an error in the AV software.

For example, when a developer makes a change to a configuration or behavior of an AV stack (and/or an associated node), such a change may cause problems (e.g., errors, etc.) with the AV stack and/or may affect the functionality of other AV stacks (and/or nodes), which in some cases may be managed by other developers and/or teams. If the change breaks or negatively impacts the functionality of an AV stack and/or associated nodes, the developers and/or teams that manage such AV stack and/or nodes may not become aware of the change that caused such issues or the timing when such issues were created, which can make it difficult to troubleshoot the problem.

Problems in the code of an AV stack (and/or a node(s)) may be discovered using end-to-end tests, where all AV stacks and nodes are tested in a simulation framework. However, such end-to-end tests are expensive to run in terms of time and compute cost, and may not be feasible for all scenarios. Moreover, when a problem associated with an AV stack and/or a node(s) arises, it can be difficult to debug the root cause of the problem. In some examples, to test AV software, developers may run simulations using one or more test scenarios configured in a simulation framework. The simulations allow developers of the AV software to test and validate the AV software before the AV software is transferred to an AV (e.g., before the AV software is released to an AV and used by the AV in real-world scenarios). Simulations can also provide a safe environment to test specific scenarios such as, for example and without limitation, edge cases which include scenarios that rarely occur in the real world (e.g., have less than a threshold probability of occurring in the real world and/or occur in less than a threshold number and/or percent of the events experienced/encountered by one or more AVs in the real world).

The challenges in testing and/or validating AV software previously described are often exacerbated by a lack of repeatability and/or a reduced repeatability of certain test scenarios in a simulation framework (e.g., of certain simulations). For example, in many cases, a test scenario, such as a particular simulation configured to test one or more aspects of the AV software (and/or associated functioning) and/or one or more scene scenarios, used to test an AV stack(s) and/or node(s) may include certain conditions, parameters, and/or errors that negatively impact the repeatability of the test scenario. The negative impact on the repeatability of a test scenario can reduce and/or put into question the reliability of the test scenario and/or the code tested using that test scenario. Thus, a decrease in the repeatability of a test scenario can decrease the reliability of the test scenario and/or the code tested using the test scenario. To illustrate, in some cases, a particular test scenario can be used in a simulation framework to test (e.g., via a simulation configured to implement/realize the test scenario) to test one or more aspects of the AV software. However, if that particular test scenario is not repeatable and/or has less than a threshold repeatability, then the test results produced by that particular test scenario when testing the one or more aspects of the AV software may not be reliable or may have less than a threshold reliability.

For example, if the test scenario is not repeatable, the lack of repeatability means that a simulation implementing the test scenario may produce different results at different times, which may be caused by certain variable(s) and/or issue in that test scenario. Thus, the lack of and/or reduced repeatability of a test scenario makes it difficult or impossible to determine whether the test scenario is truly testing the one or more aspects of the AV software that the developer(s) intends to test and/or whether the test results produced from that test scenario truly reflect how the AV software (and/or the one or more AV aspects of the AV software) will/would perform in situations involving one or more specific conditions that the developer intends to test through the simulation implementing the test scenario.

Unfortunately, given the large number of variables that can impact the repeatability of a test scenario and/or the performance (e.g., the accuracy, the safety, the effectiveness, etc.) of code tested in a simulation implementing the test scenario, it can be extremely difficult to identify what specific variables may have influenced the test results generated through the simulation implementing the test scenario and/or what specific variables may have caused the lack of repeatability of the test scenario and/or a decrease in the repeatability of the test scenario. Indeed, in many cases, it can be difficult to even determine whether a lack of or decrease in repeatability of a test scenario is caused by an issue with the test scenario and/or an issue in the code tested using that test scenario.

Systems, apparatuses, processes (also referred to as methods), and computer-readable media (collectively referred to as “systems and techniques”) are described herein for maximizing the repeatability of software tests (e.g., simulations). In some examples, the systems and techniques described herein can be used to test software (e.g., AV software), determine whether specific test scenarios are repeatable in a simulation framework, increasing a repeatability of test scenarios implemented in a simulation framework, and/or determine whether any aspects of the test scenarios and/or the code tested using the test scenarios has/have issues such as errors, unexpected and/or unknown variables that affect the test results and/or the repeatability of test results produced by the test scenario. For example, the systems and techniques described herein can be used to test AV software, maximize a repeatability of test scenarios used to test the AV software, determine whether a specific test scenario is repeatable in a simulation framework used to test the AV software, and/or determine whether any changes to the AV software code tested using the test scenario have any issues such as errors and/or unexpected results and/or behavior.

In some aspects, the systems and techniques described herein can parameterize hot starts to maximize a test repeatability. In some examples, the systems and techniques described herein can replay road data in a simulation used to test one or more aspects of an AV software, and identify a window of time within the simulation on which to parameterize. The window of time can include an interval of time on with to parameterize, and can be used to evaluate one or more aspects of the AV software. The road data (e.g., real-world data such as real-world sensor data) can include sensor data collected by one or more sensors of one or more AVs while the one or more AVs drive/navigate one or more real-world environments. This road data can identify conditions and/or events experienced by the one or more AVs, one or more errors encountered/experienced by the one or more AVs (and/or AV software implemented by the one or more AVs), etc. The road data can be replayed in a simulation used to test one or more aspects of an AV software.

In some examples, the road data can allow a certain scenario(s) (e.g., a certain scene(s), condition(s), variable(s), etc.) experienced/encountered by an AV in the real-world as reflected in sensor data collected by the AV while driving/navigating in the real-world, to be reproduced in a simulation. The simulation can be used to, for example and without limitation, test one or more changes/updates of the code of an AV software, test how an AV implementing the AV software performs in a test scenario (e.g., an environment, a testing condition(s), etc.) reproduced in the simulation, test and validate the AV software (and/or a change(s) to the code of the AV software) before the AV software is transferred to an AV (e.g., before the AV software is released to an AV and used by the AV in real-world scenarios), and/or test one or more aspects of the AV software such as, for example, one or more capabilities, operations, and/or behaviors performed and/or controlled/influenced by the AV software, etc. In some examples, the simulation can be used to test one or more AV software stacks (and/or code and/or aspects thereof) such as, for example and without limitation, a perception stack, a planning stack, a prediction stack, a control stack, a localization stack, and/or any other AV software stack(s).

For example, to test AV software, including one or more AV capabilities and/or AV software stacks, a developer can use real-world road data (e.g., data, such as sensor data, collected by one or more sensors of an AV(s) while driving/navigating in a real-world environment) collected by an AV(s) and/or experienced/encountered by the AV(s) on the road in the real-world to create a simulation used to test the AV software. The road data (e.g., including real-world sensor data) can reflect one or more events experienced/encountered by the AV(s), such as errors and/or other issues experienced/encountered by the AV(s). In some examples, the developer(s) can make one or more changes to a code of the AV software configured to correct/remediate (and/or intended to correct/remediate) any errors experienced by the AV software, configured to modify a capability and/or behavior of the AV (and/or the AV software) to avoid or better handle the one or more events experienced/encountered by the AV(s), etc. The developer(s) can use the simulation that replays the road data to test the one or more changes to the code of the AV software in order to determine (and/or validate that) whether the one or more code changes properly address the one or more events and/or correct any errors associated with the one or more events experienced/encountered by the AV(s), validate the AV software with the one or more changes to the code of the AV software, etc.

If the one or more events reflected in the road data include an error experienced/encountered by an AV (e.g., and thus the AV software) when the AV encountered a double-parked vehicle, the developer can replay the road data in a simulation to test whether one or more code changes in the AV software implemented by the developer(s) allow the AV to properly handle (or better handle) double-parked vehicles in the same and/or similar scenarios. In this example, the error experienced/encountered by the AV can include, for example, a failure to navigate around a double-parked vehicle and/or implement a certain desired maneuver when encountering a double-parked vehicle. In some cases, the developer(s) may categorize each event reflected in the road data into certain buckets that the developer(s) plans to work on to fix any issues/errors in the AV software experienced when the AV encounters the event, such as a failure to handle the double-parked vehicle (e.g., a failure to maneuver around the double-parked vehicle). To illustrate, in the previous example where the AV experienced an error/failure when encountering a double-parked vehicle, the developer(s) may implement one or more code changes intended to address the error/failure to handle double-parked vehicles. The developer(s) may also create a simulation that tests the AV software.

In some examples, the developer(s) can use the simulation to determine how to fix the AV software to avoid the issues experienced when encountering a double-parked vehicle and/or determine whether the one or more code changes properly address the error/failure to handle double-parked vehicles. Such a simulation can include replaying the road data with the AV software implementing the one or more code changes. At some point during the simulation, the behavior of the AV implementing the AV software with the one or more code changes may diverge from the behavior experienced by the AV in the real-world prior to implementing the one or more code changes. For example, the developer(s) may create a simulation to test how the behavior of the AV at some point in the simulation diverges from the actual behavior experienced by the AV in the real-world when it encountered the specific event being addressed by the one or more code changes. Depending on when the point is that the developer(s) intends to see how the AV behaves when experiencing such event (e.g., relative to how it behaved when it experienced that event in the real-world, as reflected in the road data). Generally, at this point, the developer(s) can start to see large divergences between what the AV actually did on the road (e.g., as reflected in the road data) when it experienced the event and what the simulated AV with the one or more code changes does when it encounters the event in the simulation.

However, in some cases, depending on the repeatability of the test scenario in the simulation, at least some of the divergences between the AV behavior in the real-world and the behavior of the simulated AV in the simulation may be caused by one or more variables in the test scenario and/or certain capabilities impacted by the one or more code changes other than the variables and/or capabilities that the developer(s) intends to test in the simulation. For example, if the developer wants to test whether the AV with the one or more code changes is able to go around a double-parked vehicle, there could be another event (e.g., different than the event that the developer(s) intends to test, which in this example is the AV's ability to go around a double-parked vehicle) in the test scenario (e.g., in the simulation) that causes a different behavior of the simulated AV (e.g., a divergence) relative to the actual behavior of the AV in the real-world, as reflected in the road data.

To illustrate, if the simulated AV is trying to go around a double-parked vehicle in the simulation, the simulation may include a pedestrian trying to cross the road at a certain point before (e.g., a few seconds before) the double-parked event (e.g., the double-parked vehicle), as reflected in the road data (e.g., the road data replayed in the simulation includes a pedestrian trying to cross the road before the AV experienced/encountered the double-parked vehicle). Prior to the simulation, when the AV experienced the pedestrian in the real-world (e.g., as reflected in the road data replayed in the simulation), the AV software may have ignored the pedestrian and correctly predicted that the pedestrian was not going to cross the road and, therefore, the AV did not acknowledge the pedestrian (e.g., the AV did not react to the pedestrian and/or modified its behavior to avoid the pedestrian). On the other hand, in the simulation, if the simulated AV is allowed to begin simulating its behavior in the test scenario too early (e.g., too far in time and/or space relative to the double-parked event encountered by the AV as reflected in the road data), the simulated AV with the one or more code changes may generate a new prediction of the behavior of that pedestrian, which triggers the simulated AV to perform a different behavior (e.g., slow down or stop to avoid that pedestrian) than the AV performed in the real-world (e.g., a different behavior than predicting that pedestrian would not cross and thus ignoring the pedestrian, as the AV did in the real-world).

However, as previously explained, in the real-world, the AV did not actually perform that same behavior that the simulated AV implemented in the simulation in response to detecting the pedestrian, and such behavior in response to the pedestrian may not be what the developer(s) is trying to test in the simulation. Consequently, the simulated AV may fail the test and/or may experience a large divergence relative to the AV's behavior in the real-world developer(s). In this example, the test failure and/or the large divergence was not caused by the double-parked event and/or the code changes. Consequently, the simulation may not properly test (or may not test at all) how the code changes implemented by the simulated AV perform when encountering a double-parked vehicle (e.g., the double-parked event). Thus, the simulation results may not adequately reflect the ability of the simulated AV to handle the double-parked vehicle. In other words, the test performed by the simulation may not be representative of what the AV experienced in the road in the real-world or what the developer(s) wishes/intends to test about the AV capabilities and software.

In some examples, the systems and techniques described herein can be used to ensure the repeatability of tests. For example, the systems and techniques described herein can be used to ensure that a test in simulation correctly represents and/or tests what the AV experienced in the real-world (e.g., in the road data) and the AV capabilities/behavior being tested in the simulation is/are indeed what the developer(s) intends to test. To illustrate, in the previous example where the developer(s) intends to test how the simulated AV responds to a double-parked vehicle (e.g., relative to how it responded to the double-parked vehicle in the real-world) and the test scenario includes a pedestrian detected by the AV prior to the double-parked vehicle, which the AV in the real-world correctly predicted would not cross the road and thus correctly ignored, the systems and techniques described herein can ensure that the simulated AV similarly ignores the pedestrian in the simulation, that the simulation correctly tests how the simulated AV with the code changes responds to the double-parked vehicle, and that any divergences between what the AV did in the real-world (e.g., as reflected in the road data) and what the simulated AV does in the simulation are attributed to the code changes and/or AV capabilities that the developer(s) intends to test.

In some examples, the systems and techniques described herein can use the road data to create a simulation, as previously explained. The simulation can include a simulation segment that represents an evaluation window (e.g., a window of time) that includes the time when the event that the developer(s) intends to test (e.g., the double-parked event in the previous example) occurred as well as a certain interval in time before and after the event. The systems and techniques described herein can iteratively (and automatically) shift the start and/or end time of the evaluation window in the simulation and measure any divergences experienced by the simulated AV (e.g., relative to the AV's behavior in the real-world as reflected in the road data) to identify an evaluation window that minimizes any divergences attributed to anything other than the event that the developer(s) intends to test (e.g., the double-parked event in the previous example) and/or one or more AV capabilities and/or code changes that specifically relate to the AV's behavior when experiencing the event that the developer(s) intends to test. This way, the developer(s) can ensure that the simulation indeed tests the AV's behavior when experiencing/encountering the event that the developer(s) intends to test and/or that the test scenario is repeatable (and/or the associated test results) such that any divergences between the behavior of the simulated AV and the AV in the real-world are indeed attributed to the event that the developer(s) intends to test and/or any changes in the code of the AV software.

For example, the systems and techniques described herein can iteratively test different evaluation windows to find the evaluation window that includes the event that the developer(s) intends to test and that eliminates and/or minimizes/reduces any divergences between the behavior of the simulated AV and the AV in the real-world that may be attributed to something other than the event that the developer(s) intends to test. The systems and techniques described herein can automate this process for iteratively checking different evaluation windows to find the best (e.g., most repeatable) evaluation window. Once the systems and techniques described herein identify a particular evaluation window (e.g., a particular start and end of the evaluation window that captures the event that the developer(s) intends to test), the developer(s) can release the AV in the evaluation window within the simulated scene to test the AV software's behavior when encountering the event (e.g., the AV software's response to the event). By using the identified evaluation window, the developer(s) can ensure that the test properly tests the AV software's behavior/performance when encountering the event, as opposed to other events that the developer(s) does not intend to test, and/or ensure that any divergences between the behavior of the simulated AV and the AV in the real-world are attributed to any code changes.

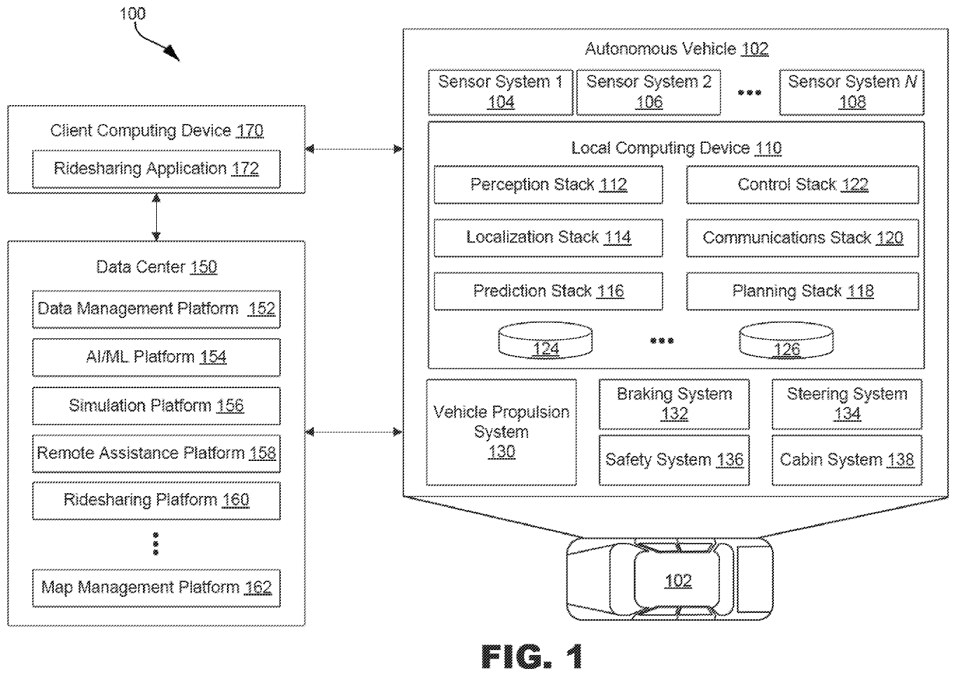

Examples of the systems and techniques described herein for processing data are illustrated in FIG. 1 through FIG. 7 and described below.

FIG. 1 is a diagram illustrating an example autonomous vehicle (AV) environment 100, according to some examples of the present disclosure. One of ordinary skill in the art will understand that, for the AV environment 100 and any system discussed in the present disclosure, there can be additional or fewer components in similar or alternative configurations. The illustrations and examples provided in the present disclosure are for conciseness and clarity. Other examples may include different numbers and/or types of elements, but one of ordinary skill the art will appreciate that such variations do not depart from the scope of the present disclosure.

In this example, the AV environment 100 includes an AV 102, a data center 150, and a client computing device 170. The AV 102, the data center 150, and the client computing device 170 can communicate with one another over one or more networks (not shown), such as a public network (e.g., the Internet, an Infrastructure as a Service (IaaS) network, a Platform as a Service (PaaS) network, a Software as a Service (SaaS) network, other Cloud Service Provider (CSP) network, etc.), a private network (e.g., a Local Area Network (LAN), a private cloud, a Virtual Private Network (VPN), etc.), and/or a hybrid network (e.g., a multi-cloud or hybrid cloud network, etc.).

The AV 102 can navigate roadways without a human driver based on sensor signals generated by sensor systems 104, 106, and 108. The sensor systems 104-108 can include one or more types of sensors and can be arranged about the AV 102. For instance, the sensor systems 104-108 can include one or more inertial measurement units (IMUs), camera sensors (e.g., still image camera sensors, video camera sensors, etc.), light sensors (e.g., LIDARs, ambient light sensors, infrared sensors, etc.), RADAR systems, GPS receivers, audio sensors (e.g., microphones, Sound Navigation and Ranging (SONAR) systems, ultrasonic sensors, etc.), engine sensors, speedometers, tachometers, odometers, altimeters, tilt sensors, impact sensors, airbag sensors, time-of-flight (TOF) sensors, seat occupancy sensors, open/closed door sensors, tire pressure sensors, rain sensors, and so forth. For example, the sensor system 104 can include a camera system, the sensor system 106 can include a LIDAR system, and the sensor system 108 can include a RADAR system. Other examples may include any other number and type of sensors.

The AV 102 can include several mechanical systems that can be used to maneuver or operate the AV 102. For instance, the mechanical systems can include a vehicle propulsion system 130, a braking system 132, a steering system 134, a safety system 136, and a cabin system 138, among other systems. The vehicle propulsion system 130 can include an electric motor, an internal combustion engine, or both. The braking system 132 can include an engine brake, brake pads, actuators, and/or any other suitable componentry configured to assist in decelerating the AV 102. The steering system 134 can include suitable componentry configured to control the direction of movement of the AV 102 during navigation. The safety system 136 can include lights and signal indicators, a parking brake, airbags, and so forth. The cabin system 138 can include cabin temperature control systems, in-cabin entertainment systems, and so forth. In some examples, the AV 102 might not include human driver actuators (e.g., steering wheel, handbrake, foot brake pedal, foot accelerator pedal, turn signal lever, window wipers, etc.) for controlling the AV 102. Instead, the cabin system 138 can include one or more client interfaces (e.g., Graphical User Interfaces (GUIs), Voice User Interfaces (VUIs), etc.) for controlling certain aspects of the mechanical systems 130-138.

The AV 102 can include a local computing device 110 that is in communication with the sensor systems 104-108, the mechanical systems 130-138, the data center 150, and/or the client computing device 170, among other systems. The local computing device 110 can include one or more processors and memory, including instructions that can be executed by the one or more processors. The instructions can make up one or more software stacks or components responsible for controlling the AV 102; communicating with the data center 150, the client computing device 170, and other systems; receiving inputs from riders, passengers, and other entities within the AV's environment; logging metrics collected by the sensor systems 104-108; and so forth. In this example, the local computing device 110 includes a perception stack 112, a mapping and localization stack 114, a prediction stack 116, a planning stack 118, a communications stack 120, a control stack 122, an AV operational database 124, and an HD geospatial database 126, among other stacks and systems.

The perception stack 112 can enable the AV 102 to “see” (e.g., via cameras, LIDAR sensors, infrared sensors, etc.), “hear” (e.g., via microphones, ultrasonic sensors, RADAR, etc.), and “feel” (e.g., pressure sensors, force sensors, impact sensors, etc.) its environment using information from the sensor systems 104-108, the mapping and localization stack 114, the HD geospatial database 126, other components of the AV, and/or other data sources (e.g., the data center 150, the client computing device 170, third party data sources, etc.). The perception stack 112 can detect and classify objects and determine their current locations, speeds, directions, and the like. In addition, the perception stack 112 can determine the free space around the AV 102 (e.g., to maintain a safe distance from other objects, change lanes, park the AV, etc.). The perception stack 112 can identify environmental uncertainties, such as where to look for moving objects, flag areas that may be obscured or blocked from view, and so forth. In some examples, an output of the prediction stack can be a bounding area around a perceived object that can be associated with a semantic label that identifies the type of object that is within the bounding area, the kinematic of the object (information about its movement), a tracked path of the object, and a description of the pose of the object (its orientation or heading, etc.).

The mapping and localization stack 114 can determine the AV's position and orientation (pose) using different methods from multiple systems (e.g., GPS, IMUs, cameras, LIDAR, RADAR, ultrasonic sensors, the HD geospatial database 126, etc.). For example, in some cases, the AV 102 can compare sensor data captured in real-time by the sensor systems 104-108 to data in the HD geospatial database 126 to determine its precise (e.g., accurate to the order of a few centimeters or less) position and orientation. The AV 102 can focus its search based on sensor data from one or more first sensor systems (e.g., GPS) by matching sensor data from one or more second sensor systems (e.g., LIDAR). If the mapping and localization information from one system is unavailable, the AV 102 can use mapping and localization information from a redundant system and/or from remote data sources.

The prediction stack 116 can receive information from the localization stack 114 and objects identified by the perception stack 112 and predict a future path for the objects. In some examples, the prediction stack 116 can output several likely paths that an object is predicted to take along with a probability associated with each path. For each predicted path, the prediction stack 116 can also output a range of points along the path corresponding to a predicted location of the object along the path at future time intervals along with an expected error value for each of the points that indicates a probabilistic deviation from that point.

The planning stack 118 can determine how to maneuver or operate the AV 102 safely and efficiently in its environment. For example, the planning stack 118 can receive the location, speed, and direction of the AV 102, geospatial data, data regarding objects sharing the road with the AV 102 (e.g., pedestrians, bicycles, vehicles, ambulances, buses, cable cars, trains, traffic lights, lanes, road markings, etc.) or certain events occurring during a trip (e.g., emergency vehicle blaring a siren, intersections, occluded areas, street closures for construction or street repairs, double-parked cars, etc.), traffic rules and other safety standards or practices for the road, user input, and other relevant data for directing the AV 102 from one point to another and outputs from the perception stack 112, localization stack 114, and prediction stack 116. The planning stack 118 can determine multiple sets of one or more mechanical operations that the AV 102 can perform (e.g., go straight at a specified rate of acceleration, including maintaining the same speed or decelerating; turn on the left blinker, decelerate if the AV is above a threshold range for turning, and turn left; turn on the right blinker, accelerate if the AV is stopped or below the threshold range for turning, and turn right; decelerate until completely stopped and reverse; etc.), and select the best one to meet changing road conditions and events. If something unexpected happens, the planning stack 118 can select from multiple backup plans to carry out. For example, while preparing to change lanes to turn right at an intersection, another vehicle may aggressively cut into the destination lane, making the lane change unsafe. The planning stack 118 could have already determined an alternative plan for such an event. Upon its occurrence, it could help direct the AV 102 to go around the block instead of blocking a current lane while waiting for an opening to change lanes.

The control stack 122 can manage the operation of the vehicle propulsion system 130, the braking system 132, the steering system 134, the safety system 136, and the cabin system 138. The control stack 122 can receive sensor signals from the sensor systems 104-108 as well as communicate with other stacks or components of the local computing device 110 or a remote system (e.g., the data center 150) to effectuate operation of the AV 102. For example, the control stack 122 can implement the final path or actions from the multiple paths or actions provided by the planning stack 118. This can involve turning the routes and decisions from the planning stack 118 into commands for the actuators that control the AV's steering, throttle, brake, and drive unit.

The communications stack 120 can transmit and receive signals between the various stacks and other components of the AV 102 and between the AV 102, the data center 150, the client computing device 170, and other remote systems. The communications stack 120 can enable the local computing device 110 to exchange information remotely over a network, such as through an antenna array or interface that can provide a metropolitan WIFI network connection, a mobile or cellular network connection (e.g., Third Generation (3G), Fourth Generation (4G), Long-Term Evolution (LTE), 5th Generation (5G), etc.), and/or other wireless network connection (e.g., License Assisted Access (LAA), Citizens Broadband Radio Service (CBRS), MULTEFIRE, etc.). The communications stack 120 can also facilitate the local exchange of information, such as through a wired connection (e.g., a user's mobile computing device docked in an in-car docking station or connected via Universal Serial Bus (USB), etc.) or a local wireless connection (e.g., Wireless Local Area Network (WLAN), Bluetooth®, infrared, etc.).

The HD geospatial database 126 can store HD maps and related data of the streets upon which the AV 102 travels. In some examples, the HD maps and related data can include multiple layers, such as an areas layer, a lanes and boundaries layer, an intersections layer, a traffic controls layer, and so forth. The areas layer can include geospatial information indicating geographic areas that are drivable (e.g., roads, parking areas, shoulders, etc.) or not drivable (e.g., medians, sidewalks, buildings, etc.), drivable areas that constitute links or connections (e.g., drivable areas that form the same road) versus intersections (e.g., drivable areas where two or more roads intersect), and so on. The lanes and boundaries layer can include geospatial information of road lanes (e.g., lane centerline, lane boundaries, type of lane boundaries, etc.) and related attributes (e.g., direction of travel, speed limit, lane type, etc.). The lanes and boundaries layer can also include three-dimensional (3D) attributes related to lanes (e.g., slope, elevation, curvature, etc.). The intersections layer can include geospatial information of intersections (e.g., crosswalks, stop lines, turning lane centerlines and/or boundaries, etc.) and related attributes (e.g., permissive, protected/permissive, or protected only left turn lanes; legal or illegal u-turn lanes; permissive or protected only right turn lanes; etc.). The traffic controls lane can include geospatial information of traffic signal lights, traffic signs, and other road objects and related attributes.

The AV operational database 124 can store raw AV data generated by the sensor systems 104-108, stacks 112-122, and other components of the AV 102 and/or data received by the AV 102 from remote systems (e.g., the data center 150, the client computing device 170, etc.). In some examples, the raw AV data can include HD LIDAR point cloud data, image data, RADAR data, GPS data, and other sensor data that the data center 150 can use for creating or updating AV geospatial data or for creating simulations of situations encountered by AV 102 for future testing or training of various machine learning algorithms that are incorporated in the local computing device 110.

The data center 150 can include a private cloud (e.g., an enterprise network, a co-location provider network, etc.), a public cloud (e.g., an Infrastructure as a Service (IaaS) network, a Platform as a Service (PaaS) network, a Software as a Service (SaaS) network, or other Cloud Service Provider (CSP) network), a hybrid cloud, a multi-cloud, and/or any other network. The data center 150 can include one or more computing devices remote to the local computing device 110 for managing a fleet of AVs and AV-related services. For example, in addition to managing the AV 102, the data center 150 may also support a ridesharing service, a delivery service, a remote/roadside assistance service, street services (e.g., street mapping, street patrol, street cleaning, street metering, parking reservation, etc.), and the like.

The data center 150 can send and receive various signals to and from the AV 102 and the client computing device 170. These signals can include sensor data captured by the sensor systems 104-108, roadside assistance requests, software updates, ridesharing pick-up and drop-off instructions, and so forth. In this example, the data center 150 includes a data management platform 152, an Artificial Intelligence/Machine Learning (AI/ML) platform 154, a simulation platform 156, a remote assistance platform 158, and a ridesharing platform 160, and a map management platform 162, among other systems.

The data management platform 152 can be a “big data” system capable of receiving and transmitting data at high velocities (e.g., near real-time or real-time), processing a large variety of data and storing large volumes of data (e.g., terabytes, petabytes, or more of data). The varieties of data can include data having different structures (e.g., structured, semi-structured, unstructured, etc.), data of different types (e.g., sensor data, mechanical system data, ridesharing service, map data, audio, video, etc.), data associated with different types of data stores (e.g., relational databases, key-value stores, document databases, graph databases, column-family databases, data analytic stores, search engine databases, time series databases, object stores, file systems, etc.), data originating from different sources (e.g., AVs, enterprise systems, social networks, etc.), data having different rates of change (e.g., batch, streaming, etc.), and/or data having other characteristics. The various platforms and systems of the data center 150 can access data stored by the data management platform 152 to provide their respective services.

The AI/ML platform 154 can provide the infrastructure for training and evaluating machine learning algorithms for operating the AV 102, the simulation platform 156, the remote assistance platform 158, the ridesharing platform 160, the map management platform 162, and other platforms and systems. Using the AI/ML platform 154, data scientists can prepare data sets from the data management platform 152; select, design, and train machine learning models; evaluate, refine, and deploy the models; maintain, monitor, and retrain the models; and so on.

The simulation platform 156 can enable testing and validation of the algorithms, machine learning models, neural networks, and other development efforts for the AV 102, the remote assistance platform 158, the ridesharing platform 160, the map management platform 162, and other platforms and systems. The simulation platform 156 can replicate a variety of driving environments and/or reproduce real-world scenarios from data captured by the AV 102, including rendering geospatial information and road infrastructure (e.g., streets, lanes, crosswalks, traffic lights, stop signs, etc.) obtained from the map management platform 162 and/or a cartography platform; modeling the behavior of other vehicles, bicycles, pedestrians, and other dynamic elements; simulating inclement weather conditions, different traffic scenarios; and so on.

The remote assistance platform 158 can generate and transmit instructions regarding the operation of the AV 102. For example, in response to an output of the AI/ML platform 154 or other system of the data center 150, the remote assistance platform 158 can prepare instructions for one or more stacks or other components of the AV 102.

The ridesharing platform 160 can interact with a customer of a ridesharing service via a ridesharing application 172 executing on the client computing device 170. The client computing device 170 can be any type of computing system such as, for example and without limitation, a server, desktop computer, laptop computer, tablet computer, smartphone, smart wearable device (e.g., smartwatch, smart eyeglasses or other Head-Mounted Display (HMD), smart ear pods, or other smart in-ear, on-ear, or over-ear device, etc.), gaming system, or any other computing device for accessing the ridesharing application 172. In some cases, the client computing device 170 can be a customer's mobile computing device or a computing device integrated with the AV 102 (e.g., the local computing device 110). The ridesharing platform 160 can receive requests to pick up or drop off from the ridesharing application 172 and dispatch the AV 102 for the trip.

Map management platform 162 can provide a set of tools for the manipulation and management of geographic and spatial (geospatial) and related attribute data. The data management platform 152 can receive LIDAR point cloud data, image data (e.g., still image, video, etc.), RADAR data, GPS data, and other sensor data (e.g., raw data) from one or more AVs 102, Unmanned Aerial Vehicles (UAVs), satellites, third-party mapping services, and other sources of geospatially referenced data. The raw data can be processed, and map management platform 162 can render base representations (e.g., tiles (2D), bounding volumes (3D), etc.) of the AV geospatial data to enable users to view, query, label, edit, and otherwise interact with the data. Map management platform 162 can manage workflows and tasks for operating on the AV geospatial data. Map management platform 162 can control access to the AV geospatial data, including granting or limiting access to the AV geospatial data based on user-based, role-based, group-based, task-based, and other attribute-based access control mechanisms. Map management platform 162 can provide version control for the AV geospatial data, such as to track specific changes that (human or machine) map editors have made to the data and to revert changes when necessary. Map management platform 162 can administer release management of the AV geospatial data, including distributing suitable iterations of the data to different users, computing devices, AVs, and other consumers of HD maps. Map management platform 162 can provide analytics regarding the AV geospatial data and related data, such as to generate insights relating to the throughput and quality of mapping tasks.

In some examples, the map viewing services of map management platform 162 can be modularized and deployed as part of one or more of the platforms and systems of the data center 150. For example, the AI/ML platform 154 may incorporate the map viewing services for visualizing the effectiveness of various object detection or object classification models, the simulation platform 156 may incorporate the map viewing services for recreating and visualizing certain driving scenarios, the remote assistance platform 158 may incorporate the map viewing services for replaying traffic incidents to facilitate and coordinate aid, the ridesharing platform 160 may incorporate the map viewing services into the client application 172 to enable passengers to view the AV 102 in transit to a pick-up or drop-off location, and so on.

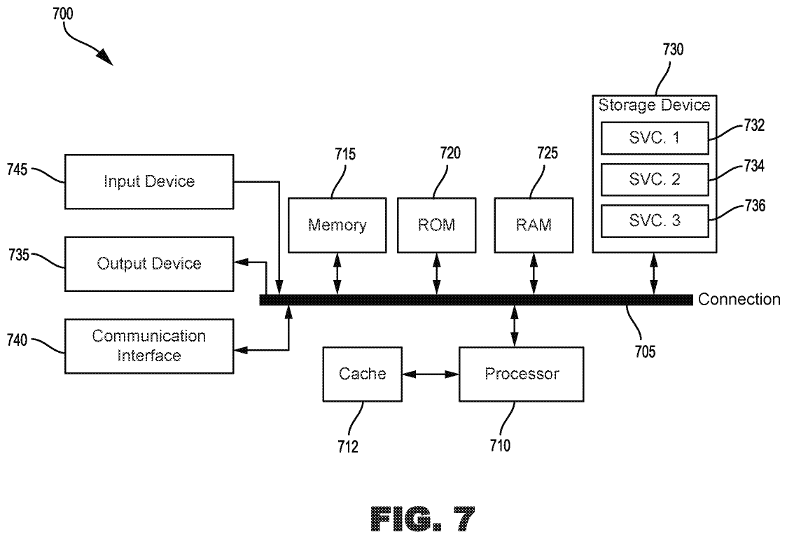

While the AV 102, the local computing device 110, and the autonomous vehicle environment 100 are shown to include certain systems and components, one of ordinary skill will appreciate that the AV 102, the local computing device 110, and/or the autonomous vehicle environment 100 can include more or fewer systems and/or components than those shown in FIG. 1. For example, the AV 102 can include other services than those shown in FIG. 1 and the local computing device 110 can, in some instances, include one or more memory devices (e.g., RAM, ROM, cache, and/or the like), one or more network interfaces (e.g., wired and/or wireless communications interfaces and the like), and/or other hardware or processing devices that are not shown in FIG. 1. An illustrative example of a computing device and hardware components that can be implemented with the local computing device 110 is described below with respect to FIG. 7.

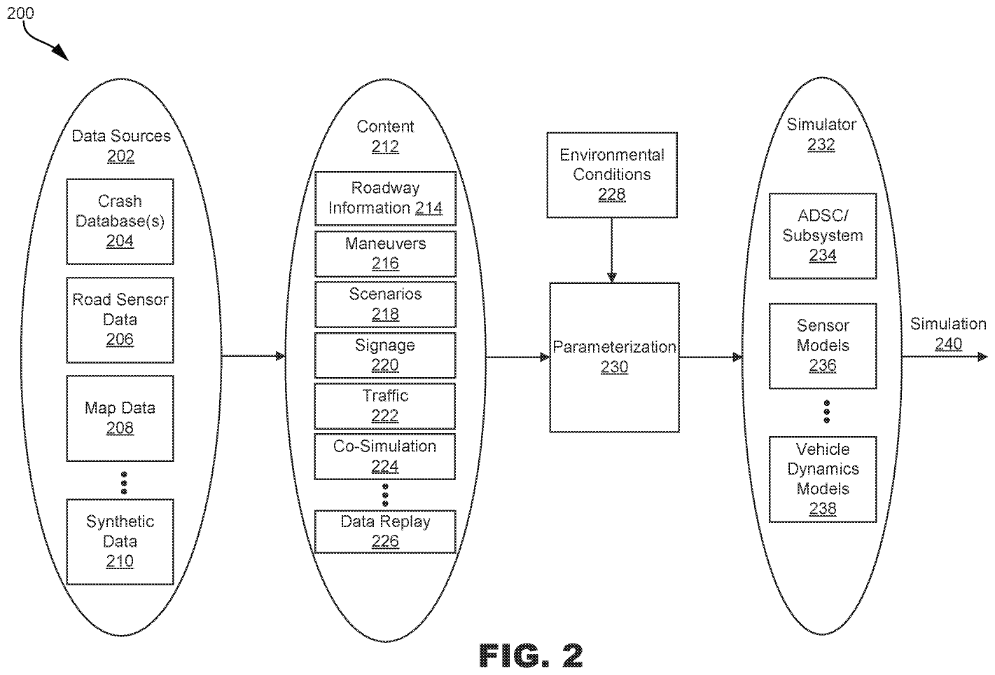

FIG. 2 is a diagram illustrating an example simulation framework 200, according to some examples of the present disclosure. The example simulation framework 200 can include data sources 202, content 212, environmental conditions 228, parameterization 230, and simulator 232. The components in the example simulation framework 200 are merely illustrative examples provided for explanation purposes. In other examples, the simulation framework 200 can include other components that are not shown in FIG. 2 and/or more or less components than shown in FIG. 2.

The data sources 202 can be used to create a simulation. The data sources 202 can include, for example and without limitation, one or more crash databases 204, road sensor data 206, map data 208, and/or synthetic data 210. In other examples, the data sources 202 can include more or less sources than shown in FIG. 2 and/or one or more data sources that are not shown in FIG. 2.

The crash databases 204 can include crash data (e.g., data describing crashes and/or associated details) generated by vehicles involved in crashes. The road sensor data 206 can include data collected by one or more sensors (e.g., one or more camera sensors, LIDAR sensors, RADAR sensors, SONAR sensors, IMU sensors, GPS/GNSS receivers, and/or any other sensors) of one or more vehicles while the one or more vehicles drive/navigate one or more real-world environments. The map data 208 can include one or more maps (and, in some cases, associated data) such as, for example and without limitation, one or more high-definition (HD) maps, sensor maps, scene maps, and/or any other maps. In some examples, the one or more HD maps can include roadway information such as, for example, lane widths, location of road signs and traffic lights, directions of travel for each lane, road junction information, speed limit information, etc.

The synthetic data 210 can include virtual assets, objects, and/or elements created for a simulated scene, a virtual scene and/or virtual scene elements, and/or any other synthetic data elements. For example, in some cases, the synthetic data 210 can include one or more virtual vehicles, virtual pedestrians, virtual roads, virtual objects, virtual environments/scenes, virtual signs, virtual backgrounds, virtual buildings, virtual trees, virtual motorcycles/bicycles, virtual obstacles, virtual environmental elements (e.g., weather, lightening, shadows, etc.), virtual surfaces, etc.

In some examples, data from some or all of the data sources 202 can be used to create the content 212. The content 212 can include static content and/or dynamic content. For example, the content 212 can include roadway information 214, maneuvers 216, scenarios 218, signage 220, traffic 222, co-simulation 224, and/or data replay 226. The roadway information 214 can include, for example, lane information (e.g., number of lanes, lane widths, directions of travel for each lane, etc.), the location and information of road signs and/or traffic lights, road junction information, speed limit information, road attributes (e.g., surfaces, angles of inclination, curvatures, obstacles, etc.), road topologies, and/or other roadway information. The maneuvers 216 can include any AV maneuvers, and the scenarios 218 can include specific AV behaviors in certain AV scenes/environments. The signage 220 can include signs such as, for example, traffic lights, road signs, billboards, displayed messages on the road, etc. The traffic 222 can include any traffic information such as, for example, traffic density, traffic fluctuations, traffic patterns, traffic activity, delays, positions of traffic, velocities, volumes of vehicles in traffic, geometries or footprints of vehicles, pedestrians, spaces (occupied and/or unoccupied), etc.

The co-simulation 224 can include a distributed modeling and simulation of different AV subsystems that form the larger AV system. In some cases, the co-simulation 224 can include information for connecting separate simulations together with interactive communications. In some cases, the co-simulation 224 can allow for modeling to be done at a subsystem level while providing interfaces to connect the subsystems to the rest of the system (e.g., the autonomous driving system computer). Moreover, the data replay 226 can include replay content produced from real-world sensor data (e.g., road sensor data 206).

The environmental conditions 228 can include any information about environmental conditions 228. For example, the environmental conditions 228 can include atmospheric conditions, road/terrain conditions (e.g., surface slope or gradient, surface geometry, surface coefficient of friction, road obstacles, etc.), illumination, weather, road and/or scene conditions resulting from one or more environmental conditions, etc.

The content 212 and the environmental conditions 228 can be used to create the parameterization 230. The parameterization 230 can include parameter ranges, parameterized scenarios, probability density functions of one or more parameters, sampled parameter values, parameter spaces to be tested, evaluation windows for evaluating a behavior of an AV in a simulation, scene parameters, content parameters, environmental parameters, etc. The parameterization 230 can be used by a simulator 232 to generate a simulation 240.

The simulator 232 can include a software engine(s), algorithm(s), neural network model(s), and/or software component(s) used to generate simulations, such as simulation 240. In some examples, the simulator 232 can include ADSC/subsystem models 234, sensor models 236, and a vehicle dynamics model 238. The ADSC/subsystem models 234 can include models, descriptors, and/or interfaces for the autonomous driving system computer (ADSC) and/or ADSC subsystems such as, for example, a perception stack (e.g., perception stack 112), a localization stack (e.g., localization stack 114), a prediction stack (e.g., prediction stack 116), a planning stack (e.g., planning stack 118), a communications stack (e.g., communications stack 120), a control stack (e.g., control stack 122), a sensor system(s), and/or any other subsystems.

The sensor models 236 can include mathematical representations of hardware sensors and an operation (e.g., sensor data processing) of one or more sensors (e.g., a LIDAR, a RADAR, a SONAR, a camera sensor, an IMU, and/or any other sensor). The vehicle dynamics model 238 can model vehicle behaviors/operations, vehicle attributes, vehicle trajectories, vehicle positions, etc.

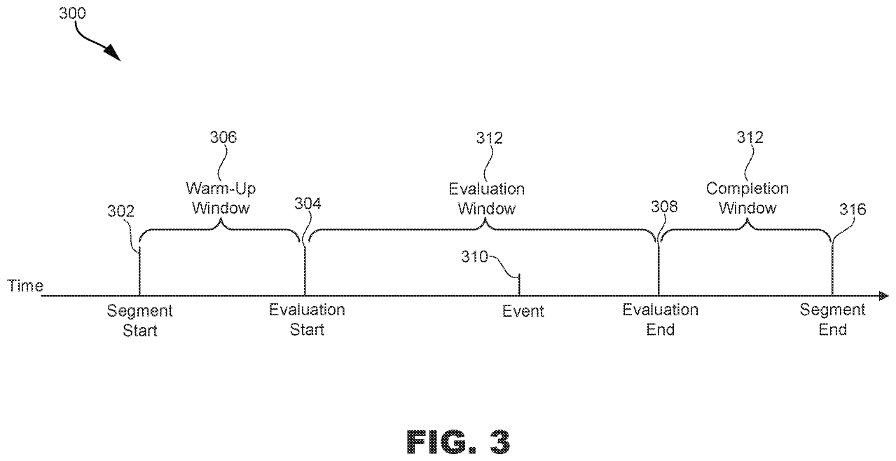

FIG. 3 is a diagram illustrating an example simulation segment 300, according to some examples of the present disclosure. The example simulation segment 300 includes a representation of a simulation timeline that can be iteratively adjusted by the systems and techniques described herein to find an evaluation window with a maximum and/or highest repeatability from a plurality of candidate evaluation windows within the simulation segment 300. In some examples, a computer (e.g., local computing device 110 or any computer) running a simulator (e.g., simulator 232) can generate (e.g., via the simulator) the example simulation segment 300 based at least partly on real-world sensor data (e.g., road sensor data 206) collected by one or more sensors of one or more AVs as the one or more AVs drive/navigate a real-world environment.

For example, AV 102 can use sensor systems 104-108 to collect sensor data while driving/navigating a real-world environment. The sensor data can measure and/or describe various characteristics of the real-world environment surrounding the AV 102 when the AV 102 collects the sensor data and any events experienced/encountered by the AV 102 while driving/navigating in the real-world environment. Such sensor data can be replayed in a simulation framework, such as the example simulation framework 200 shown in FIG. 2. In some examples, the simulator 232 shown in FIG. 2 can use the sensor data to generate a simulation that includes the example simulation segment 300. In some cases, the simulator 232 can additionally use data from other sources (e.g., other sources from the data sources 202) to generate content (e.g., content 212) used to create the simulation.

As shown in FIG. 3, the simulation segment 300 can include a segment start 302 and a segment end 316. The segment start 302 can include a point in time for the beginning of the simulation segment 300 and the segment end 316 can include a point in time for the end of the simulation segment 300. In some examples, the segment start 302 can begin at an interval of time before an evaluation start time 304, which corresponds to a point in time when an evaluation window 312 starts. The evaluation window 312 can include a window of time for testing an AV software and/or a behavior of an AV (e.g., AV 102). For example, the window of time associated with the evaluation window 312 can include a time when an event of interest (e.g., an event that a developer(s) intends to test such as the double-parked event in the previous example) occurred, as well as a respective interval in time before and after the event, which in FIG. 3 are represented by the evaluation start time 304 and an evaluation end time 308.

The segment start 302 can be located at a point in time within the simulation segment 300 relative to (e.g., prior to) the evaluation start time 304. For example, in some cases, the segment start 302 can be determined based on an interval of time prior to the evaluation start time 304. Such interval of time can correspond to and/or create a warm-up window 306. The warm-up window 306 can include a time interval from the segment start 302 until the evaluation start time 304.

In some examples, the warm-up window 306 can provide time (e.g., a period of time) to the AV (e.g., AV 102) to run some or all of the AV software stacks and begin collecting sensor data associated with an environment of the AV and/or begin understanding the environment of the AV. For example, in some cases, the warm-up window 306 can provide a certain amount of time for the AV software stacks, excluding the planning stack and the control stack of the AV, to initialize. In some cases, a pose of the simulation AV (e.g., the AV in the simulation associated with the simulation segment 300) in the simulation segment 300 (e.g., in the warm-up window 306) can be clamped to a pose of the AV in the real-world at one or more points in time within the warm-up window 306, as reflected in the road sensor data (e.g., road sensor data 206). For example, the simulator 232 can analyze the road sensor data (e.g., road sensor data 206) to determine a pose of the AV when the AV drove/navigated in an environment corresponding to the simulation segment 300. The simulator 232 can then clamp a pose of the simulation AV in the simulation segment 300 to the pose of the AV in the real-world when driving/navigating the environment corresponding to the simulation segment 300, as reflected in the road sensor data. To clamp the pose of the simulation AV to the pose of the AV in the real-world as reflected in the road sensor data, the simulator 232 can set a pose of the simulation AV within one or more points in time in the simulation segment 300 (e.g., within one or more points in time within the warm-up window 306) to match a pose of the AV in the real-world at the one or more points in time in the simulation segment 300, as reflected in the road sensor data.

After the warm-up window 306, the evaluation start time 304 can mark the beginning of the evaluation window 312. After the evaluation window 312, the simulation segment 300 can include a completion window 314 that includes a period of time from the evaluation end time 308 and the segment end 316. In some examples, the completion window 314 can include a cool-down period for the AV and the software stacks of the AV.

As previously explained, the evaluation window 312 can include the time when the event 310 took place in the real-world. The event 310 can be recorded and/or measured by the road sensor data and replayed (e.g., using the road sensor data) in the simulation associated with the simulation segment 300. The replayed event (e.g., event 310) in simulation can be used to test the AV's behavior in simulation when encountering such event, as further described herein. For example, if a developer(s) modifies a code of the AV software to try to fix any issues with the code that may have caused an error/failure when encountering the event 310 and/or tries to add/modify one or more AV capabilities for handling the event 310 (and/or the type of event associated with the event 310), the developer(s) can test the modified code in a simulation that includes the event 310 to determine whether the modified code indeed has fixed whatever issue the AV software had when encountering the event 310. The simulated AV can calculate metrics throughout the evaluation window 312 including the event 310, which can indicate how the simulated AV performed in the simulation when encountering the event 310. The metrics can include, for example and without limitation, safety metrics, performance metrics, comfort metrics, accuracy metrics, metrics measuring and/or describing a behavior of the AV when encountering the event 310 in simulation, and/or any other metrics.

The event 310 can include any type of event encountered by the AV in the real-world and intended for testing through the simulation. For example, the event 310 can include an error experienced by the AV, a problem experienced by the AV, a failure experienced by the AV, a malfunction experienced by the AV, and/or divergence from an expected or desired behavior of the AV. To illustrate, assume the AV in the real-world encounters a double-parked vehicle and, at the time, the AV was unable to perform an expected and/or desired maneuver in response to the double-parked vehicle. In this example, the event 310 can include the time when the AV encountered the double-parked vehicle and/or a failure of the AV to perform an expected and/or desired maneuver in response to the double-parked vehicle. The road sensor data collected by the AV when the AV encountered the double-parked vehicle can reflect the event including the AV encountering the double-parked vehicle and the AV's failure to perform the expected and/or desired maneuver in response to the double-parked vehicle. Thus, when the road sensor data is replayed in the simulation, the road sensor data can recreate the event when the AV encountered the double-parked vehicle and/or failed to perform the expected and/or desired maneuver in response to the double-parked vehicle.

In some examples, the evaluation window 312 can include a time within the simulation associated with the simulation segment 300 in which the simulator 232 releases the simulated AV within the simulated environment and begins collecting sensor data in the simulated environment and using the software stacks of the AV to drive/navigate within the simulated environment. Thus, the behavior of the simulated AV in the evaluation window 312 can be analyzed to determine how the software stacks of the AV handle the event 310 when the simulated AV encounters/experiences the event 310 in the simulation. For example, the behavior of the simulated AV in the evaluation window 312 can be analyzed to determine any divergences between the AVs behavior when the AV encountered/experienced the event 310 in the real-world (e.g., as reflected in the road sensor data) and the behavior of the simulated AV when the simulated AV encountered/experienced the event 310 in the simulation.

As previously noted, the pose of the simulated AV in the warm-up window 306 can be clamped to the pose of the AV at the same point(s) in time in the real-world relative to the event 310 (e.g., the pose of the simulated AV can be set to match the pose of the AV in the real-world at one or more points in time within the warm-up window 306). Thus, when the simulator 232 releases the simulated AV to the simulated environment at the evaluation window 312, the simulated AV can begin with a pose matching the pose of the AV in the real-world at a time(s) corresponding to the evaluation window 312. At the evaluation window 312 within the simulation, the simulator 232 can allow the simulated AV to collect sensor data and drive/navigate to analyze how the simulated AV behaves when encountering the event 310 relative to how the AV behaved when encountering the event 310 in the real-world.

The simulated AV can start at the evaluation window 312 with a pose matching the pose of the AV in the real-world (e.g., the clamped pose) at a time corresponding to the evaluation start time 304 within the simulation segment 300 and the evaluation window 312. Thus, at the beginning of the evaluation window 312, the pose of the simulated AV can match the pose of the AV in the real-world at a corresponding time. Once the simulated AV is released within the evaluation window 312 of the simulation, the pose of the simulated AV can be unclamped. Instead, the pose of the simulated AV at (and/or throughout) the evaluation window 312 can be simulated to show how the simulated AV behaves within the evaluation window 312, including when the simulated AV encounters the event 310. Therefore, as the simulated AV drives/navigates within the evaluation window 312 in the simulation and the pose of the simulated AV is unclamped and simulated, the behavior of the simulated AV and the behavior of the AV in the real-world can begin to diverge.

The divergence between the simulated AV and the AV in the real-world can show how the simulated AV handles the event 310 relative to (e.g., different than) how the AV handled the event 310 in the real-world, as reflected in the road data. Therefore, the divergence can represent the AV's behavior in simulation (e.g., the simulated behavior of the AV) with respect to the event 310 and relative to the AV's behavior in the real-world with respect to the event 310.

As previously explained, to increase or maximize the repeatability of the test scenario corresponding to the simulation (e.g., corresponding to the simulated segment 300), the simulator 232 can iteratively shift the evaluation start time 304 and/or the evaluation end time 308 to determine a configuration of the evaluation window (e.g., a certain evaluation start and end time) that ensures or provides an increased or maximum test repeatability for simulating and testing the behavior of the AV when encountering the event 310. The increased or maximum test repeatability can ensure that any divergences between the behavior of the AV in simulation when encountering the event 310 and the behavior of the AV in the real-world when encountering the event 310 are attributed to changes in the code of the AV and not to a non-repeatability/non-determinism of the simulation test and/or the AV software.

For example, the increased or maximum test repeatability can ensure that any divergences between the behavior of the AV in simulation when encountering the event 310 and the behavior of the AV in the real-world when encountering the event 310 are attributed to changes in the code of the AV and not to other variables in the simulation test and/or the AV software. This way, when the simulator 232 tests the AV's behavior and/or performance when encountering the event 310 in simulation, the simulator 232 can ensure that the simulation test is correctly testing the AV's ability to handle the event 310 as opposed to some other variable(s) in the test and/or the AV software.

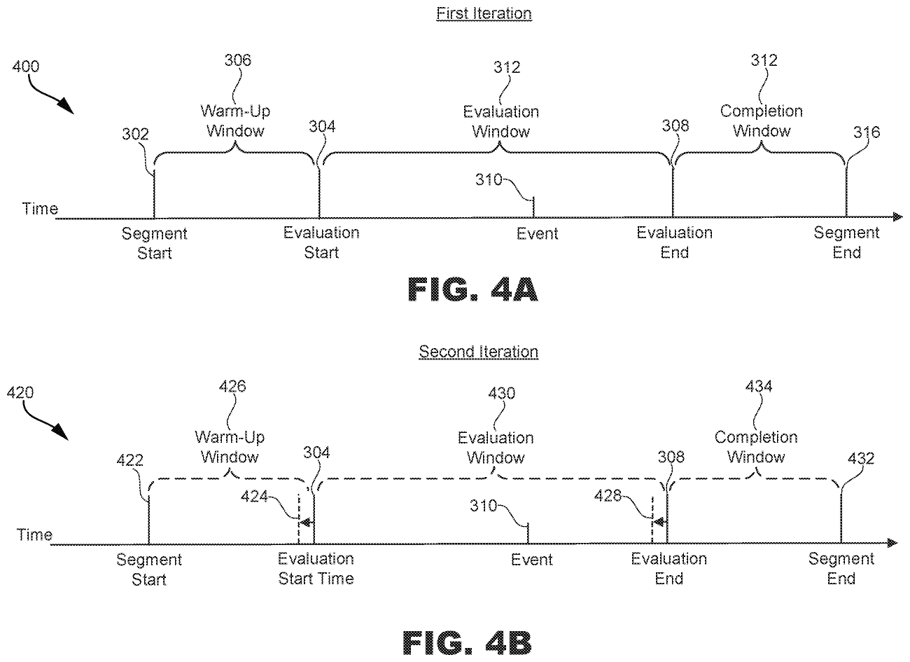

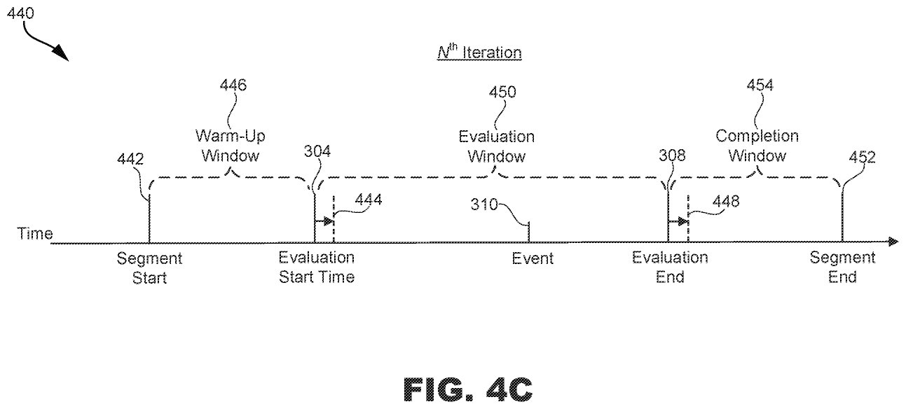

FIG. 4A through 4C are diagrams illustrating various example simulation segments generated by the simulator 232 at various iterations implemented to determine a particular evaluation window that ensures or provides an increased or maximum test repeatability for simulating and testing the behavior of the AV when encountering the event 310.

Specifically, FIG. 4A shows an example simulation segment generated at a first iteration 400. In this example, the simulation segment generated at the first iteration 400 can match or can be the same as the simulation segment 300 shown in FIG. 3. For example, at the first iteration, the simulation segment can include the segment start 302 and the segment end 316. Within the segment start 302 and the segment end 316, the simulation segment can include the warm-up period 306, the evaluation window 312 including the event 310, and the completion window 314.

At the second iteration 420 shown in FIG. 4B, the simulator 232 has generated a different evaluation window 430. The different evaluation window 430 can include a different evaluation start 424 (e.g., relative to the evaluation start 304 in the first iteration 400) and/or a different evaluation end 428 (e.g., relative to the evaluation end 308 in the first iteration 400). For example, in the second iteration 420, the simulator 232 can shift the evaluation start 304 from the first iteration 400 to match the evaluation start 424 shown in FIG. 4B, and/or can shift the evaluation end 308 from the first iteration 400 to match the evaluation end 428 shown in FIG. 4B. The simulator 232 can release the simulated AV at the evaluation window 430 in the second iteration 420 and unclamp the pose of the simulated AV so the pose of the simulated AV in the evaluation window 430 is simulated rather than clamped to (e.g., set to match) the pose of the AV in the real-world at a time interval relative to the event 310 corresponding to the evaluation window 430.

By shifting the evaluation window in the second iteration 420, the simulator 232 also shifts the warm-up window and/or the completion window relative to the warm-up window 306 and/or the completion window 314 in the first iteration 400. For example, if the second iteration 420 shifts the evaluation start from the evaluation start 304 shown in FIG. 4A to the evaluation start 424 shown in FIG. 4B, the simulator 232 also shifts the segment start 422 and thus the warm-up window 426 in the second iteration 420. Similarly, if the second iteration 420 additionally or alternatively shifts the evaluation end from the evaluation end 308 shown in FIG. 4A to the evaluation end 428 shown in FIG. 4B, the simulator 232 also shifts the segment end 432 and thus the completion window 434 in the second iteration 420.

When the simulator 232 releases the simulated AV within the evaluation window 430 in the simulation, the simulator 232 can simulate a pose and behavior of the AV throughout the evaluation window 430. In some examples, within the evaluation window 430 in the simulation, the AV can collect and process sensor data and use the sensor data to control a pose and behavior of the AV throughout the evaluation window 430 according to the capabilities of the AV (e.g., of the AV software) and the behavior of the AV produced by the software stacks of the AV. Moreover, the simulated AV can collect metrics throughout the simulated operation/behavior of the AV in the evaluation window 430. The metrics can be indicative of a behavior and/or performance of the AV within the evaluation window 430 of the simulation.

The simulator 232 can use the metrics collected throughout the evaluation window 430 to determine whether the evaluation window 430 is properly/accurately calibrated to ensure or provide an increased or maximum test repeatability for simulating and testing the behavior of the AV when encountering the event 310. In other words, the simulator 232 can analyze the metrics collected throughout the evaluation window 430 to determine whether any divergences between the AV pose and/or behavior in the simulation (e.g., in the evaluation window 430) and the AV pose and/or behavior in the real-world when encountering the event 310 are attributed to code changes made to the AV software as opposed to other variables in the test simulation and/or the AV software. This way, the simulator 232 can ensure that the simulation, including the evaluation window 430, and/or the metrics collected in the evaluation window 430 is/are indeed representative of the AV's capabilities with respect to the event 310 (e.g., with respect to the AV's capabilities for handling and/or responding to the event 310). In other words, the simulator 232 can ensure that the simulation including the evaluation window 430, and/or the metrics collected in the evaluation window 430, is/are indeed testing what the developer(s) intends to test, which in this example includes how the AV responds to the event 310, the AV's ability to respond to the event 310, and/or the portion of code in the AV software that controls and/or affects how the AV responds to the event 310.

In some examples, the simulator 232 can automatically perform the first iteration 400 and the second iteration 420 as part of the process for determining the final evaluation window for the simulation. The simulator 232 can perform one or more additional iterations to determine the final evaluation window. For example, FIG. 4C illustrates an n^{th} iteration 440 for determining or fine-tuning the evaluation window for the simulation, where n is a positive number greater than 1.

At the n^{th} iteration 440 shown in FIG. 4C, the simulator 232 has generated a different evaluation window 450 than the evaluation window 312 shown in FIG. 4A and the evaluation window 450 shown in FIG. 4B. The different evaluation window 450 can include a different evaluation end 444 (e.g., relative to the evaluation start 304 in the first iteration 400 and/or the evaluation start 422 in the second iteration 420) and/or a different evaluation end 448 (e.g., relative to the evaluation end 308 in the first iteration 400 and/or the evaluation end 428 in the second iteration 420). For example, in the n^{th} iteration 440, the simulator 232 can shift the evaluation start 424 from the second iteration 420 to match the evaluation start 444 shown in FIG. 4C, and/or can shift the evaluation end 428 from the second iteration 420 to match the evaluation end 448 shown in FIG. 4C. The simulator 232 can release the simulated AV at the evaluation window 450 in the n^{th} iteration 440 and unclamp the pose of the simulated AV so the pose of the simulated AV in the evaluation window 450 is simulated rather than clamped to (e.g., set to match) the pose of the AV in the real-world at a time interval relative to the event 310 corresponding to the evaluation window 450.

By shifting the evaluation window in the n^{th} iteration 440, the simulator 232 also shifts the warm-up window and/or the completion window relative to the warm-up window 426 in the second iteration 420 and/or the completion window 434 in the second iteration 420. For example, if the n^{th} iteration 440 shifts the evaluation start from the evaluation start 424 shown in FIG. 4B to the evaluation start 444 shown in FIG. 4C, the simulator 232 also shifts the segment start 442 and thus the warm-up window 446 in the n^{th} iteration 440. Similarly, if the n^{th} iteration 440 additionally or alternatively shifts the evaluation end from the evaluation end 428 shown in FIG. 4B to the evaluation end 448 shown in FIG. 4C, the simulator 232 also shifts the segment end 452 and thus the completion window 454 in the n^{th} iteration 440.

When the simulator 232 releases the simulated AV within the evaluation window 450 in the simulation, the simulator 232 can simulate a pose and behavior of the AV throughout the evaluation window 450. In some examples, within the evaluation window 450 in the simulation, the AV can collect and process sensor data and use the sensor data to control a pose and behavior of the AV throughout the evaluation window 450 according to the capabilities of the AV (e.g., of the AV software) and the behavior of the AV produced by the software stacks of the AV. Moreover, the simulated AV can collect metrics throughout the simulated operation/behavior of the AV in the evaluation window 450. The metrics can be indicative of a behavior and/or performance of the AV within the evaluation window 450 of the simulation.

The simulator 232 can use the metrics collected throughout the evaluation window 450 to determine whether the evaluation window 450 is properly/accurately calibrated to ensure or provide an increased or maximum test repeatability for simulating and testing the behavior of the AV when encountering the event 310. In other words, the simulator 232 can analyze the metrics collected throughout the evaluation window 450 to determine whether any divergences between the AV pose and/or behavior in the simulation (e.g., in the evaluation window 450) and the AV pose and/or behavior in the real-world when encountering the event 310 are attributed to code changes made to the AV software as opposed to other variables in the test simulation and/or the AV software. This way, the simulator 232 can ensure that the simulation, including the evaluation window 450, and/or the metrics collected in the evaluation window 450 is/are indeed representative of the AV's capabilities with respect to the event 310 (e.g., with respect to the AV's capabilities for handling and/or responding to the event 310). In other words, the simulator 232 can ensure that the simulation including the evaluation window 450, and/or the metrics collected in the evaluation window 450, is/are indeed testing what the developer(s) intends to test, which in this example includes how the AV responds to the event 310, the AV's ability to respond to the event 310, and/or the portion of code in the AV software that controls and/or affects how the AV responds to the event 310.

The simulator 232 can perform as many iterations as it deems necessary to determine the final evaluation window that increases and/or maximizes the repeatability of the test simulation. In FIG. 4C, the evaluation window 450 represents the final evaluation window determined by the simulator 232. However, the iterative process for determining the final evaluation window for testing the AV stacks of the AV can include more or less iterations than shown in FIGS. 4A through 4C.

The simulator 232 can compare the pose, behavior, and/or metrics of the AV throughout the various evaluation windows (e.g., evaluation window 312, evaluation window 430, evaluation window 450) in the various iterations (e.g., the first iteration 400, the second iteration 420, the n^{th} iteration 440) to determine the final evaluation window (e.g., evaluation window 450) for the simulation. For example, the simulator 232 can compare the poses, behaviors, and/or metrics of the AV in the evaluation window 312 from the first iteration 400, the evaluation window 430 from the second iteration 420, and the evaluation window 450 from the n^{th} iteration 440. Based on the comparison, the simulator 232 can identify the evaluation window that is most representative of the developer(s) intends to test about the AV software, that results in a simulation test with the highest test repeatability, and/or that includes the least amount of variables impacting a behavior and/or AV software of the AV that the developer(s) intends to test. In other words, based on the comparison, the simulator 232 can identify the evaluation window that includes the least number and/or magnitude of divergences between the AV's behavior in simulation (with respect to the event 310) and the AV's behavior in the real-world (with respect to the event 310) attributable to something other than any changes in the code of the AV software corresponding to the AV capabilities for handling the event 310 and/or the AV capabilities with respect to the event 310.

In some cases, to identify the final evaluation window, the simulator 232 can determine which evaluation window (e.g., evaluation window 312, evaluation window 430, or evaluation window 450) has the least number and/or magnitude of variables and/or divergences attributable to something other than any changes in the code of the AV software corresponding to the AV capabilities for handling the event 310 and/or the AV capabilities with respect to the event 310.

For example, assume that the simulator 232 determines that divergences in AV metrics and/or behavior associated with the evaluation window 450 and relative to the AV metrics and/or behavior experienced by the AV in the real-world when encountering the event 310, are all attributable to changes in a code of the AV software corresponding to the AV's capabilities to handle the event 310. Assume that the simulator 232 also determines that certain divergences in AV metrics and/or behavior associated with the evaluation window 312 and the evaluation window 430 (and relative to the AV metrics and/or behavior experienced by the AV in the real-world when encountering the event 310) are attributable to something other than changes in a code of the AV software corresponding to the AV's capabilities to handle the event 310, the simulator 232 can identify the evaluation window 450 as the final evaluation window and/or the evaluation window with the most repeatability characteristics (e.g., the evaluation window that results in a simulation test that is most representative of what the developer(s) intends to test about the AV software and/or capabilities with respect to the event 310).

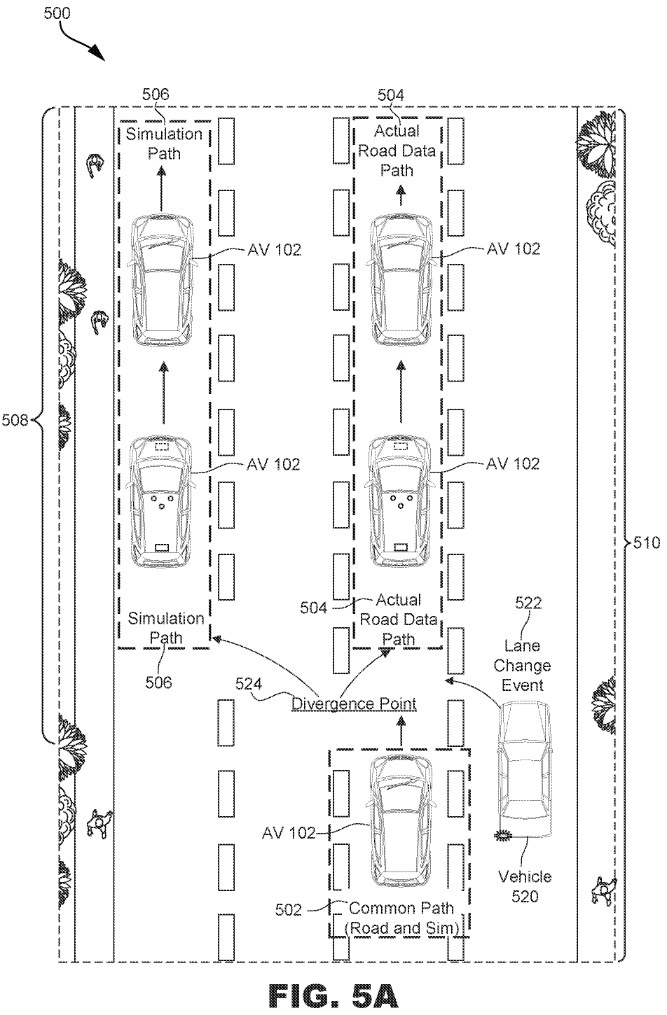

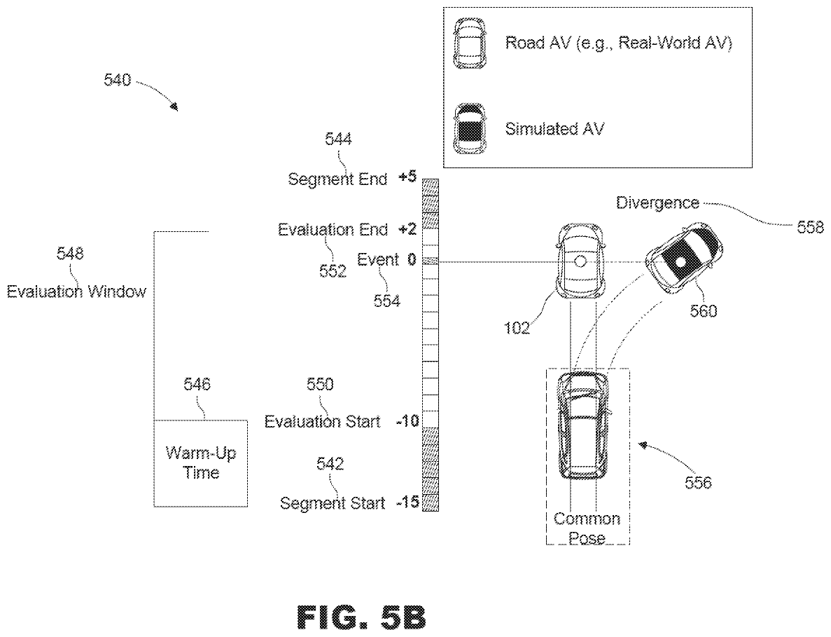

FIG. 5A is a diagram illustrating an example simulation 500 showing a divergence between a simulation path and an actual road data path (e.g., an actual path of the AV in the real-world as reflected by road sensor data collected in the real-world), according to some examples of the present disclosure. In this example, the simulation 500 includes a common path 502 between the AV 102 in the simulation 500 and the AV 102 in the real-world at the time that the road sensor data used to generate the simulation 500 (e.g., replayed in the simulation 500) was collected by the AV 102. In some examples, the common path 502 can reflect a common pose of the AV 102 in the simulation 500 and the real-world. For example, the common path 502 can reflect a pose of the AV 102 in a warm-up window (e.g., warm-up window 306, warm-up window 426, or warm-up window 446) within the simulation segment 510 of the simulation 500. In this example, the pose of the AV 102 in the simulation 500 is clamped to match the pose of the AV 102 in the real-world (e.g., at the same time relative to an event (e.g., event 310) being tested) at the time the road sensor data replayed in the simulation 500 was collected.

At some point when the AV 102 in the common path 502 reaches the evaluation window 508 being tested/analyzed, the pose, path, and/or behavior of the AV 102 in the simulation 500 can be allowed to diverge from the pose, path, and/or behavior of the AV 102 in the real-world, based on the AV capabilities and/or the AV software implemented in the simulation. The pose, path, and/or behavior of the AV 102 can be allowed to diverge in order to test the behavior and/or performance of the AV 102 in the simulation 500. In other words, at some point when the AV 102 in the common path 502 reaches the evaluation window 508 being tested/analyzed, the pose, path, and/or behavior of the AV 102 can be simulated in the simulation framework, at which point the pose, path, and/or behavior of the AV 102 in the simulation 500 can diverge from the pose, path, and/or behavior of the AV 102 in the real-world. Such divergence can be based on the AV capabilities and/or the AV software implemented in the simulation relative to the AV capabilities and/or AV software of the AV 102 when the road sensor data used to generate the simulation 500. For example, as previously explained, the final evaluation window (e.g., evaluation window 508) used in the simulation 500 can include the best/most repeatability characteristics and/or score, and/or can be most representative of the AV aspects that the simulation 500 intends to test.

As shown in FIG. 5A, after the common path 502, the AV 102 encounters a divergence point 524 where the pose and path of the AV 102 in the simulation 500 diverges from the pose and path of the AV 102 in the real-world. After the divergence point 524, the AV 102 in the simulation 500 can proceed to the simulation path 506, while the AV 102 in the real-world followed the actual road data path 504, which represents the pose and path of the AV 102 reflected in the road sensor data. The divergence point 524 can be at least partly triggered by an event 522 being tested in the simulation 500. In this example, the event 522 includes a lane change event of a vehicle 520 on the road. The lane change event includes the vehicle 520 attempting to change lanes to move onto a lane used by the AV 102 at a point time and/or location in space in which the change in lanes by the vehicle 520 would cause the vehicle 520 to potentially collide with the AV 102 if the AV 102 does not implement a collision avoidance maneuver. In other words, the location of the vehicle 520 after the lane change event can overlap with the location of the AV 102 when the vehicle 520 completes the lane change event, which can potentially cause the AV 102 and the vehicle 520 to collide.

As shown in FIG. 5A, the AV 102 in the real-world did not alter its pose or trajectory via a collision avoidance maneuver to avoid the vehicle 520 switching to the lane used by the AV 102. Thus, the developer(s) of the AV software of the AV 102 may use the simulation 500 to fix the failure of the AV 102 in the real-world to implement the collision avoidance maneuver, as reflected in the actual road data path 504, and test any code changes made to ensure that the AV 102 is able to and/or correctly performs the collision avoidance maneuver to avoid a vehicle switching to a lane of the AV 102 at a point in time and/or space that may result in a collision between the AV 102 and the other vehicle if the AV 102 does not perform the collision avoidance maneuver.

In the simulation 500, at the divergence point 524, the AV 102 is shown following a different path than the AV 102 followed in the real-world. In particular, instead of continuing in the actual road data path 504, the AV 102 in the simulation 500 correctly performed the collision avoidance maneuver which resulted in the AV 102 switching lanes to avoid the vehicle 520 and continuing along the simulated path 506.

FIG. 5B is a diagram illustrating another example simulation 540 showing a divergence between a simulation path and an actual real-world path of an AV, according to some examples of the present disclosure. In this example, the AV 102 is shown with a particular pose at the time of an event 554 being tested (e.g., an event of interest). The simulated AV 560 is shown with a different pose than the AV 102 at a divergence point 558 at the time of (or around the time of) the event 554.

The simulation 540 includes a segment start 542 and a segment end 544. Within the segment start 542 and the segment end 544, the simulation 540 includes a warm-up time 546 which includes a period of time for initiating/initializing one or more software stacks of the AV. The pose of the simulated AV 560 at the warm-up time 546 can be clamped to match the pose of the AV 102 in the real-world at a moment in time and/or space relative to the event 554. For example, the simulated AV 560 and the AV 102 in the real-world can have a common pose 556 at the evaluation start 542 which can diverge at the divergence point 558 upon encountering the event 554.

The simulation 540 can include an evaluation window 548 determined as previously explained with respect to FIGS. 2, 3A, 3B, and 3C. The evaluation window 548 can include an evaluation start 550 and an evaluation end 552. The event 554 can be within the evaluation window 548. For example, the event 554 can be after the evaluation start 550 but before the evaluation end 552. The pose of the simulated AV 560 within the evaluation window 548 can be simulated to test the behavior of the AV when encountering the event 554. Thus, the pose of the simulated AV 560 can be unclamped at the evaluation start 550 so it is not predefined to match the pose of the AV 102 in the real-world, but rather allowed to diverge in order to test the AVs capabilities with respect to the event 554.

The evaluation start 550 and/or the evaluation end 552 can be shifted in time to determine the final evaluation window as previously explained. For example, the simulator 232 can shift evaluation start 550 and/or the evaluation end 552 in one or more iterations to find the evaluation start and end that increases and/or maximizes a repeatability of the simulation test and ensure that the evaluation window is most representative of the intended test of the AV's behavior when encountering the event 554.

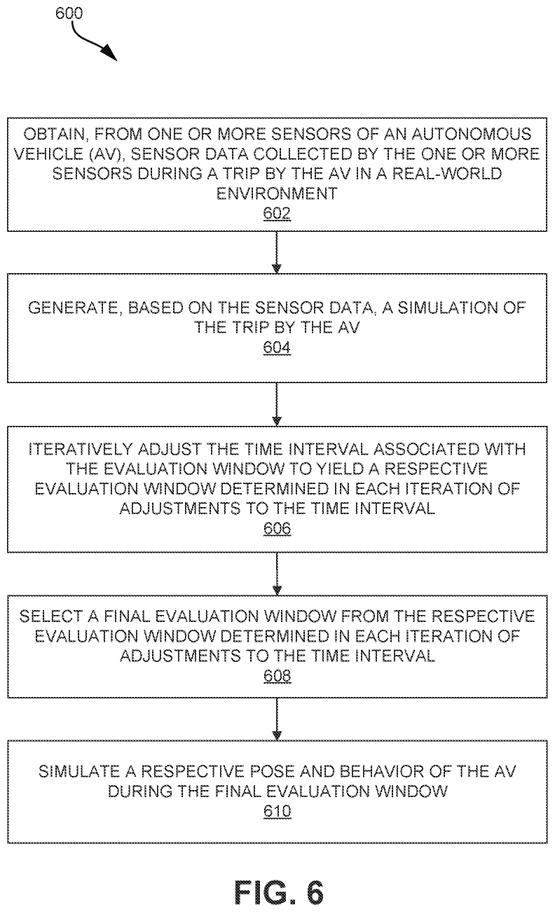

FIG. 6 is a flowchart illustrating an example process 600 for running AV simulation tests and maximizing a repeatability of the AV simulation tests, according to some examples of the present disclosure. At block 602, the process 600 can include obtaining, from one or more sensors (e.g., sensor system 104, sensor system 106, sensor system 108) of an autonomous vehicle (AV) (e.g., AV 102), sensor data (e.g., road sensor data 206) collected by the one or more sensors during a trip by the AV in a real-world environment. In some examples, the sensor data can reflect a pose and behavior of the AV implemented in response to an event (e.g., event 310) encountered by the AV in the real-world environment.

In some examples, the event can include an error experienced by the AV, a failure experienced by the AV, and/or an incident encountered by the AV in which a response of the AV to the incident did not match an intended or expected response of the AV when encountering the incident.

At block 604, the process 600 can include generating, based on the sensor data, a simulation of the trip by the AV. In some examples, the simulation can include an evaluation window in which to test a simulated pose and behavior of the AV in association with one or more changes to a software of the AV. The evaluation window can include a time interval within a segment (e.g., simulation segment 300) of the trip by the AV that includes the event encountered by the AV in the real-world environment.

At block 606, the process 600 can include iteratively adjusting the time interval associated with the evaluation window to yield a respective evaluation window (e.g., evaluation window 312, evaluation window 430, evaluation window 450) determined in each iteration of adjustments to the time interval. In some examples, each respective evaluation window can include a respective time interval. The respective time interval can include a respective evaluation start (e.g., evaluation start 304, evaluation start 424, evaluation start 444), the event (e.g., event 310), and a respective evaluation end (e.g., evaluation end 308, evaluation end 428, evaluation end 448).

At block 608, the process 600 can include selecting a final evaluation window (e.g., evaluation window 450) from the respective evaluation window determined in each iteration of adjustments to the time interval. In some examples, the final evaluation window can be selected based on a comparison of AV metrics calculated from each respective simulation of a pose and behavior of the AV during each respective evaluation window and/or divergences between the pose and behavior of the AV during each respective evaluation window and an additional pose and behavior of the AV during the trip by the AV in the real-world environment.

In some cases, the final evaluation window can be selected, from the respective simulation of the pose and behavior of the AV determined in each iteration of adjustments, based on a determination that the divergences between the pose and behavior of the AV during each respective evaluation window and the additional pose and behavior of the AV during the trip by the AV in the real-world environment are attributed to the one or more changes to the software of the AV.

In other cases, the final evaluation window can additionally or alternatively be selected, from the respective simulation of the pose and behavior of the AV determined in each iteration of adjustments, based on a determination that a difference between one or more first AV metrics calculated from a respective simulation of the pose and behavior of the AV during the final evaluation window and one or more second AV metrics collected during the trip by the AV in the real-world environment relate to the event and the one or more changes to the software of the AV. In some examples, the final evaluation window is selected further based on a determination that respective differences between AV metrics calculated from respective simulations of the pose and behavior of the AV during a set of evaluation windows and additional AV metrics collected during the trip by the AV in the real-world environment where caused by a different event, one or more portions of the software of the AV that are unrelated to one or more capabilities of the AV designed to handle the event, a non-repeatable feature of an AV software test involving the respective simulations, and/or a non-deterministic feature of the software of the AV, wherein the set of evaluation windows excludes the final evaluation window.

In some examples, the one or more first AV metrics and the one or more second AV metrics can include a performance metric, a safety metric, and/or an accuracy metric.

At block 610, the process 600 can include simulating a respective pose and behavior of the AV during the final evaluation window.

In some aspects, the process 600 can include setting a first pose of the AV at a point prior to the respective evaluation window within each respective simulation to match a second pose of the AV at a corresponding point during the trip by the AV in the real-world environment; and allowing a third pose of the AV during the respective evaluation window within each respective simulation to differ from a fourth pose of the AV at an additional corresponding point during the trip by the AV in the real-world environment.

In some examples, simulating the respective pose and behavior of the AV during the final evaluation window can include collecting metrics associated with the AV while simulating the respective pose and behavior of the AV during the final evaluation window. In some aspects, the process 600 can include determining, based on the metrics associated with the AV collected while simulating the respective pose and behavior of the AV during the final evaluation window, whether the one or more changes to the software of the AV correct an error and/or a failure experienced by the AV when at least one of encountering the event and responding to the event.

In some aspects, the process 600 can include determining a respective repeatability score for each respective simulation of the pose and behavior of the AV during each respective evaluation window; and selecting the final evaluation window further based on the respective repeatability score for each respective simulation of the pose and behavior of the AV during each respective evaluation window. In some examples, the respective repeatability score can be determined by comparing data (e.g., metrics, divergences, pose information, behavior information, etc.) about the trip of the AV in the real-world environment and data (e.g., metrics, divergences, pose information, behavior information, etc.) about each respective simulation of the pose and behavior of the AV during each evaluation window.

For example, the respective repeatability score for a simulation of a pose and behavior of the AV can be determined by comparing metrics, divergences (e.g., in pose, behavior, path, and/or metrics), and/or sensor data associated with the simulation and the trip by the AV in the real-world environment. In some cases, the respective repeatability score can be determined further based on a determination regarding whether any divergences in metrics, pose, behavior, and/or paths between the trip by the AV in the real-world environment and the simulation are attributed to the event and one or more changes to the software of the AV or whether they are attributed to one or more other things such as, for example and without limitation, a non-repeatability feature of the simulation and/or associated test scenario, a non-deterministic feature of the software of the AV, a different event, and/or one or more other portions of the software of the AV that do not relate to the AV's capability to respond to, and/or handle, the event.

FIG. 7 illustrates an example processor-based system with which some aspects of the subject technology can be implemented. For example, processor-based system 700 can be any computing device making up local computing device 110, remote computing system 190, a passenger device (e.g., client computing device 170) executing the ridesharing application 172, or any component thereof in which the components of the system are in communication with each other using connection 705. Connection 705 can be a physical connection via a bus, or a direct connection into processor 710, such as in a chipset architecture. Connection 705 can also be a virtual connection, networked connection, or logical connection.

In some examples, computing system 700 is a distributed system in which the functions described in this disclosure can be distributed within a datacenter, multiple data centers, a peer network, etc. In some examples, one or more of the described system components represents many such components each performing some or all of the function for which the component is described. In some aspects, the components can be physical or virtual devices.

Example system 700 includes at least one processing unit (CPU or processor) 710 and connection 705 that couples various system components including system memory 715, such as read-only memory (ROM) 720 and random-access memory (RAM) 725 to processor 710. Computing system 700 can include a cache of high-speed memory 712 connected directly with, in close proximity to, and/or integrated as part of processor 710.

Processor 710 can include any general-purpose processor and a hardware service or software service, such as services 732, 734, and 736 stored in storage device 730, configured to control processor 710 as well as a special-purpose processor where software instructions are incorporated into the actual processor design. Processor 710 may essentially be a completely self-contained computing system, containing multiple cores or processors, a bus, memory controller, cache, etc. A multi-core processor may be symmetric or asymmetric.

To enable user interaction, computing system 700 can include an input device 745, which can represent any number of input mechanisms, such as a microphone for speech, a touch-sensitive screen for gesture or graphical input, keyboard, mouse, motion input, speech, etc. Computing system 700 can also include output device 735, which can be one or more of a number of output mechanisms known to those of skill in the art. In some instances, multimodal systems can enable a user to provide multiple types of input/output to communicate with computing system 700. Computing system 700 can include communications interface 740, which can generally govern and manage the user input and system output. The communication interface may perform or facilitate receipt and/or transmission wired or wireless communications via wired and/or wireless transceivers, including those making use of an audio jack/plug, a microphone jack/plug, a universal serial bus (USB) port/plug, an Apple® Lightning® port/plug, an Ethernet port/plug, a fiber optic port/plug, a proprietary wired port/plug, a BLUETOOTH® wireless signal transfer, a BLUETOOTH® low energy (BLE) wireless signal transfer, an IBEACON® wireless signal transfer, a radio-frequency identification (RFID) wireless signal transfer, near-field communications (NFC) wireless signal transfer, dedicated short range communication (DSRC) wireless signal transfer, 802.11 Wi-Fi wireless signal transfer, wireless local area network (WLAN) signal transfer, Visible Light Communication (VLC), Worldwide Interoperability for Microwave Access (WiMAX), Infrared (IR) communication wireless signal transfer, Public Switched Telephone Network (PSTN) signal transfer, Integrated Services Digital Network (ISDN) signal transfer, 3G/4G/9G/LTE cellular data network wireless signal transfer, ad-hoc network signal transfer, radio wave signal transfer, microwave signal transfer, infrared signal transfer, visible light signal transfer, ultraviolet light signal transfer, wireless signal transfer along the electromagnetic spectrum, or some combination thereof.

Communications interface 740 may also include one or more Global Navigation Satellite System (GNSS) receivers or transceivers that are used to determine a location of the computing system 700 based on receipt of one or more signals from one or more satellites associated with one or more GNSS systems. GNSS systems include, but are not limited to, the US-based Global Positioning System (GPS), the Russia-based Global Navigation Satellite System (GLONASS), the China-based BeiDou Navigation Satellite System (BDS), and the Europe-based Galileo GNSS. There is no restriction on operating on any particular hardware arrangement, and therefore the basic features here may easily be substituted for improved hardware or firmware arrangements as they are developed.

Storage device 730 can be a non-volatile and/or non-transitory computer-readable memory device and can be a hard disk or other types of computer readable media which can store data that are accessible by a computer, such as magnetic cassettes, flash memory cards, solid state memory devices, digital versatile disks, cartridges, a floppy disk, a flexible disk, a hard disk, magnetic tape, a magnetic strip/stripe, any other magnetic storage medium, flash memory, memristor memory, any other solid-state memory, a compact disc read only memory (CD-ROM) optical disc, a rewritable compact disc (CD) optical disc, digital video disk (DVD) optical disc, a blu-ray disc (BDD) optical disc, a holographic optical disk, another optical medium, a secure digital (SD) card, a micro secure digital (microSD) card, a Memory Stick® card, a smartcard chip, a EMV chip, a subscriber identity module (SIM) card, a mini/micro/nano/pico SIM card, another integrated circuit (IC) chip/card, random access memory (RAM), static RAM (SRAM), dynamic RAM (DRAM), read-only memory (ROM), programmable read-only memory (PROM), erasable programmable read-only memory (EPROM), electrically erasable programmable read-only memory (EEPROM), flash EPROM (FLASHEPROM), cache memory (L1/L2/L3/L4/L9/L#), resistive random-access memory (RRAM/ReRAM), phase change memory (PCM), spin transfer torque RAM (STT-RAM), another memory chip or cartridge, and/or a combination thereof.

Storage device 730 can include software services, servers, services, etc., that when the code that defines such software is executed by the processor 710, causes the system to perform a function. In some examples, a hardware service that performs a particular function can include the software component stored in a computer-readable medium in connection with the necessary hardware components, such as processor 710, connection 705, output device 735, etc., to carry out the function.

As understood by those of skill in the art, machine-learning techniques can vary depending on the desired implementation. For example, machine-learning schemes can utilize one or more of the following, alone or in combination: hidden Markov models; recurrent neural networks; convolutional neural networks (CNNs); deep learning; Bayesian symbolic methods; general adversarial networks (GANs); support vector machines; image registration methods; applicable rule-based system. Where regression algorithms are used, they may include including but are not limited to: a Stochastic Gradient Descent Regressor, and/or a Passive Aggressive Regressor, etc.

Machine learning classification models can also be based on clustering algorithms (e.g., a Mini-batch K-means clustering algorithm), a recommendation algorithm (e.g., a Miniwise Hashing algorithm, or Euclidean Locality-Sensitive Hashing (LSH) algorithm), and/or an anomaly detection algorithm, such as a Local outlier factor. Additionally, machine-learning models can employ a dimensionality reduction approach, such as, one or more of: a Mini-batch Dictionary Learning algorithm, an Incremental Principal Component Analysis (PCA) algorithm, a Latent Dirichlet Allocation algorithm, and/or a Mini-batch K-means algorithm, etc.

Aspects within the scope of the present disclosure may also include tangible and/or non-transitory computer-readable storage media or devices for carrying or having computer-executable instructions or data structures stored thereon. Such tangible computer-readable storage devices can be any available device that can be accessed by a general purpose or special purpose computer, including the functional design of any special purpose processor as described above. By way of example, and not limitation, such tangible computer-readable devices can include RAM, ROM, EEPROM, CD-ROM or other optical disk storage, magnetic disk storage or other magnetic storage devices, or any other device which can be used to carry or store desired program code in the form of computer-executable instructions, data structures, or processor chip design. When information or instructions are provided via a network or another communications connection (either hardwired, wireless, or combination thereof) to a computer, the computer properly views the connection as a computer-readable medium. Thus, any such connection is properly termed a computer-readable medium. Combinations of the above should also be included within the scope of the computer-readable storage devices.

Computer-executable instructions include, for example, instructions and data which cause a general-purpose computer, special-purpose computer, or special-purpose processing device to perform a certain function or group of functions. By way of example, computer-executable instructions can be used to implement perception system functionality for determining when sensor cleaning operations are needed or should begin. Computer-executable instructions can also include program modules that are executed by computers in stand-alone or network environments. Generally, program modules include routines, programs, components, data structures, objects, and the functions inherent in the design of special-purpose processors, etc. that perform tasks or implement abstract data types. Computer-executable instructions, associated data structures, and program modules represent examples of the program code means for executing steps of the methods disclosed herein. The particular sequence of such executable instructions or associated data structures represents examples of corresponding acts for implementing the functions described in such steps.

Other examples of the disclosure may be practiced in network computing environments with many types of computer system configurations, including personal computers, hand-held devices, multi-processor systems, microprocessor-based or programmable consumer electronics, network PCs, minicomputers, mainframe computers, and the like. Aspects of the disclosure may also be practiced in distributed computing environments where tasks are performed by local and remote processing devices that are linked (either by hardwired links, wireless links, or by a combination thereof) through a communications network. In a distributed computing environment, program modules can be located in both local and remote memory storage devices.

The various examples described above are provided by way of illustration only and should not be construed to limit the scope of the disclosure. For example, the principles herein apply equally to optimization as well as general improvements. Various modifications and changes may be made to the principles described herein without following the example aspects and applications illustrated and described herein, and without departing from the spirit and scope of the disclosure.

Claim language or other language in the disclosure reciting “at least one of” a set and/or “one or more” of a set indicates that one member of the set or multiple members of the set (in any combination) satisfy the claim. For example, claim language reciting “at least one of A and B” or “at least one of A or B” means A, B, or A and B. In another example, claim language reciting “at least one of A, B, and C” or “at least one of A, B, or C” means A, B, C, or A and B, or A and C, or B and C, or A and B and C. The language “at least one of” a set and/or “one or more” of a set does not limit the set to the items listed in the set. For example, claim language reciting “at least one of A and B” or “at least one of A or B” can mean A, B, or A and B, and can additionally include items not listed in the set of A and B.

Illustrative examples of the disclosure include:

Aspect 1. A system comprising: memory; and one or more processors coupled to the memory, the one or more processors being configured to: obtain, from one or more sensors of an autonomous vehicle (AV), sensor data collected by the one or more sensors during a trip by the AV in a real-world environment, wherein the sensor data reflects a pose and behavior of the AV implemented in response to an event encountered by the AV in the real-world environment; generate, based on the sensor data, a simulation of the trip by the AV, the simulation comprising an evaluation window in which to test a simulated pose and behavior of the AV associated with one or more changes to a software of the AV, the evaluation window comprising a time interval within a segment of the trip by the AV that includes the event encountered by the AV in the real-world environment; iteratively adjust the time interval associated with the evaluation window to yield a respective evaluation window determined in each iteration of adjustments to the time interval, each respective evaluation window comprising a respective time interval comprising a respective evaluation start, the event, and a respective evaluation end; select a final evaluation window from the respective evaluation window determined in each iteration of adjustments to the time interval, the final evaluation window being selected based on a comparison of at least one of AV metrics calculated from each respective simulation of a pose and behavior of the AV during each respective evaluation window and divergences between the pose and behavior of the AV during each respective evaluation window and an additional pose and behavior of the AV during the trip by the AV in the real-world environment; and simulate a respective pose and behavior of the AV during the final evaluation window.

Aspect 2. The system of Aspect 1, wherein the final evaluation window is selected, from the respective simulation of the pose and behavior of the AV determined in each iteration of adjustments, based on a determination that the divergences between the pose and behavior of the AV during each respective evaluation window and the additional pose and behavior of the AV during the trip by the AV in the real-world environment are attributed to the one or more changes to the software of the AV.

Aspect 3. The system of Aspect 1 or 2, wherein the final evaluation window is selected, from the respective simulation of the pose and behavior of the AV determined in each iteration of adjustments, based on a determination that a difference between one or more first AV metrics calculated from a respective simulation of the pose and behavior of the AV during the final evaluation window and one or more second AV metrics collected during the trip by the AV in the real-world environment relate to the event and the one or more changes to the software of the AV.

Aspect 4. The system of Aspect 3, wherein the final evaluation window is selected further based on a determination that respective differences between AV metrics calculated from respective simulations of the pose and behavior of the AV during a set of evaluation windows and additional AV metrics collected during the trip by the AV in the real-world environment where caused by at least one of a different event, one or more portions of the software of the AV that are unrelated to one or more capabilities of the AV designed to handle the event, a non-repeatable feature of an AV software test involving the respective simulations, and a non-deterministic feature of the software of the AV, wherein the set of evaluation windows excludes the final evaluation window.

Aspect 5. The system of Aspect 3 or 4, wherein the one or more first AV metrics and the one or more second AV metrics comprise at least one of a performance metric, a safety metric, and an accuracy metric.

Aspect 6. The system of any of Aspects 1 to 5, wherein the one or more processors are configured to: set a first pose of the AV at a point prior to the respective evaluation window within each respective simulation to match a second pose of the AV at a corresponding point during the trip by the AV in the real-world environment; and allow a third pose of the AV during the respective evaluation window within each respective simulation to differ from a fourth pose of the AV at an additional corresponding point during the trip by the AV in the real-world environment.

Aspect 7. The system of claim 1, wherein simulating the respective pose and behavior of the AV during the final evaluation window comprises collecting metrics associated with the AV while simulating the respective pose and behavior of the AV during the final evaluation window.

Aspect 8. The system of Aspect 7, wherein the one or more processors are configured to: based on the metrics associated with the AV collected while simulating the respective pose and behavior of the AV during the final evaluation window, determine whether the one or more changes to the software of the AV correct at least one of an error and a failure experienced by the AV when at least one of encountering the event and responding to the event.

Aspect 9. The system of any of Aspects 1 to 8, wherein the system comprises the AV, and wherein the event comprises at least one of an error experienced by the AV, a failure experienced by the AV, and an incident encountered by the AV in which a response of the AV to the incident did not match an intended or expected response of the AV when encountering the incident.

Aspect 10. The system of any of Aspects 1 to 9, wherein the one or more processors are configured to: determine a respective repeatability score for each respective simulation of the pose and behavior of the AV during each respective evaluation window; and select the final evaluation window further based on the respective repeatability score for each respective simulation of the pose and behavior of the AV during each respective evaluation window.

Aspect 11. A method comprising: obtaining, from one or more sensors of an autonomous vehicle (AV), sensor data collected by the one or more sensors during a trip by the AV in a real-world environment, wherein the sensor data reflects a pose and behavior of the AV implemented in response to an event encountered by the AV in the real-world environment; generating, based on the sensor data, a simulation of the trip by the AV, the simulation comprising an evaluation window in which to test a simulated pose and behavior of the AV associated with one or more changes to a software of the AV, the evaluation window comprising a time interval within a segment of the trip by the AV that includes the event encountered by the AV in the real-world environment; iteratively adjusting the time interval associated with the evaluation window to yield a respective evaluation window determined in each iteration of adjustments to the time interval, each respective evaluation window comprising a respective time interval comprising a respective evaluation start, the event, and a respective evaluation end; selecting a final evaluation window from the respective evaluation window determined in each iteration of adjustments to the time interval, the final evaluation window being selected based on a comparison of at least one of AV metrics calculated from each respective simulation of a pose and behavior of the AV during each respective evaluation window and divergences between the pose and behavior of the AV during each respective evaluation window and an additional pose and behavior of the AV during the trip by the AV in the real-world environment; and simulating a respective pose and behavior of the AV during the final evaluation window.

Aspect 12. The method of Aspect 11, wherein the final evaluation window is selected, from the respective simulation of the pose and behavior of the AV determined in each iteration of adjustments, based on a determination that the divergences between the pose and behavior of the AV during each respective evaluation window and the additional pose and behavior of the AV during the trip by the AV in the real-world environment are attributed to the one or more changes to the software of the AV.

Aspect 13. The method of Aspect 11 or 12, wherein the final evaluation window is selected, from the respective simulation of the pose and behavior of the AV determined in each iteration of adjustments, based on a determination that a difference between one or more first AV metrics calculated from a respective simulation of the pose and behavior of the AV during the final evaluation window and one or more second AV metrics collected during the trip by the AV in the real-world environment relate to the event and the one or more changes to the software of the AV.

Aspect 14. The method of Aspect 13, wherein the final evaluation window is selected further based on a determination that respective differences between AV metrics calculated from respective simulations of the pose and behavior of the AV during a set of evaluation windows and additional AV metrics collected during the trip by the AV in the real-world environment where caused by at least one of a different event, one or more portions of the software of the AV that are unrelated to one or more capabilities of the AV designed to handle the event, a non-repeatable feature of an AV software test involving the respective simulations, and a non-deterministic feature of the software of the AV, wherein the set of evaluation windows excludes the final evaluation window.

Aspect 15. The method of Aspect 13 or 14, wherein the one or more first AV metrics and the one or more second AV metrics comprise at least one of a performance metric, a safety metric, and an accuracy metric.

Aspect 16. The method of any of Aspects 11 to 15, further comprising: setting a first pose of the AV at a point prior to the respective evaluation window within each respective simulation to match a second pose of the AV at a corresponding point during the trip by the AV in the real-world environment; and allowing a third pose of the AV during the respective evaluation window within each respective simulation to differ from a fourth pose of the AV at an additional corresponding point during the trip by the AV in the real-world environment.

Aspect 17. The method of any of Aspects 11 to 16, wherein simulating the respective pose and behavior of the AV during the final evaluation window comprises collecting metrics associated with the AV while simulating the respective pose and behavior of the AV during the final evaluation window.

Aspect 18. The method of Aspect 17, further comprising: based on the metrics associated with the AV collected while simulating the respective pose and behavior of the AV during the final evaluation window, determining whether the one or more changes to the software of the AV correct at least one of an error and a failure experienced by the AV when at least one of encountering the event and responding to the event.

Aspect 19. The method of any of Aspects 11 to 18, wherein the event comprises at least one of an error experienced by the AV, a failure experienced by the AV, and an incident encountered by the AV in which a response of the AV to the incident did not match an intended or expected response of the AV when encountering the incident.

Aspect 20. The method of any of Aspects 11 to 19, further comprising: determining a respective repeatability score for each respective simulation of the pose and behavior of the AV during each respective evaluation window; and selecting the final evaluation window further based on the respective repeatability score for each respective simulation of the pose and behavior of the AV during each respective evaluation window.

Aspect 21. A non-transitory computer-readable medium having stored thereon instructions which, when executed by one or more processors, cause the one or more processors to perform a method according to any of Aspects 11 to 20.

Aspect 22. A system comprising means for performing a method according to any of Aspects 11 to 20.

Aspect 23. A computer-program product comprising instructions which, when executed by one or more processors, cause the one or more processors to perform a method according to any of Aspects 11 to 20.

Aspect 24. An autonomous vehicle comprising a computing device having stored thereon instructions which, when executed by the computing device, cause the computing device to perform a method according to any of Aspects 11 to 20.

What is claimed is:

1. A system comprising:
a memory; and
one or more processors coupled to the memory, the one or more processors being configured to:
obtain, from one or more sensors of an autonomous vehicle (AV), sensor data collected by the one or more sensors during a trip by the AV in a real-world environment, wherein the sensor data reflects a pose and behavior of the AV implemented in response to an event encountered by the AV in the real-world environment;
generate, based on the sensor data, a simulation of the trip by the AV, the simulation comprising an evaluation window in which to test a simulated pose and behavior of the AV associated with one or more changes to a software of the AV, the evaluation window comprising a time interval within a segment of the trip by the AV that includes the event encountered by the AV in the real-world environment;
iteratively adjust the time interval associated with the evaluation window to yield a respective evaluation window determined in each iteration of adjustments to the time interval, each respective evaluation window comprising a respective time interval comprising a respective evaluation start, the event, and a respective evaluation end;
select a final evaluation window from the respective evaluation window determined in each iteration of adjustments to the time interval, the final evaluation window being selected based on a comparison of at least one of AV metrics calculated from each respective simulation of a pose and behavior of the AV during each respective evaluation window and divergences between the pose and behavior of the AV during each respective evaluation window and an additional pose and behavior of the AV during the trip by the AV in the real-world environment; and
simulate a respective pose and behavior of the AV during the final evaluation window.

2. The system of claim 1, wherein the final evaluation window is selected, from the respective simulation of the pose and behavior of the AV determined in each iteration of adjustments, based on a determination that the divergences between the pose and behavior of the AV during each respective evaluation window and the additional pose and behavior of the AV during the trip by the AV in the real-world environment are attributed to the one or more changes to the software of the AV.

3. The system of claim 1, wherein the final evaluation window is selected, from the respective simulation of the pose and behavior of the AV determined in each iteration of adjustments, based on a determination that a difference between one or more first AV metrics calculated from a respective simulation of the pose and behavior of the AV during the final evaluation window and one or more second AV metrics collected during the trip by the AV in the real-world environment relate to the event and the one or more changes to the software of the AV.

4. The system of claim 3, wherein the final evaluation window is selected further based on a determination that respective differences between AV metrics calculated from respective simulations of the pose and behavior of the AV during a set of evaluation windows and additional AV metrics collected during the trip by the AV in the real-world environment where caused by at least one of a different event, one or more portions of the software of the AV that are unrelated to one or more capabilities of the AV designed to handle the event, a non-repeatable feature of an AV software test involving the respective simulations, and a non-deterministic feature of the software of the AV, wherein the set of evaluation windows excludes the final evaluation window.

5. The system of claim 3, wherein the one or more first AV metrics and the one or more second AV metrics comprise at least one of a performance metric, a safety metric, and an accuracy metric.

6. The system of claim 1, wherein the one or more processors are configured to:
set a first pose of the AV at a point prior to the respective evaluation window within each respective simulation to match a second pose of the AV at a corresponding point during the trip by the AV in the real-world environment; and
allow a third pose of the AV during the respective evaluation window within each respective simulation to differ from a fourth pose of the AV at an additional corresponding point during the trip by the AV in the real-world environment.

7. The system of claim 1, wherein simulating the respective pose and behavior of the AV during the final evaluation window comprises collecting metrics associated with the AV while simulating the respective pose and behavior of the AV during the final evaluation window.

8. The system of claim 7, wherein the one or more processors are configured to:
based on the metrics associated with the AV collected while simulating the respective pose and behavior of the AV during the final evaluation window, determine whether the one or more changes to the software of the AV correct at least one of an error and a failure experienced by the AV when at least one of encountering the event and responding to the event.

9. The system of claim 1, wherein the system comprises the AV, and wherein the event comprises at least one of an error experienced by the AV, a failure experienced by the AV, and an incident encountered by the AV in which a response of the AV to the incident did not match an intended or expected response of the AV when encountering the incident.

10. The system of claim 1, wherein the one or more processors are configured to:
determine a respective repeatability score for each respective simulation of the pose and behavior of the AV during each respective evaluation window; and
select the final evaluation window further based on the respective repeatability score for each respective simulation of the pose and behavior of the AV during each respective evaluation window.

11. A method comprising:
obtaining, from one or more sensors of an autonomous vehicle (AV), sensor data collected by the one or more sensors during a trip by the AV in a real-world environment, wherein the sensor data reflects a pose and behavior of the AV implemented in response to an event encountered by the AV in the real-world environment;
generating, based on the sensor data, a simulation of the trip by the AV, the simulation comprising an evaluation window in which to test a simulated pose and behavior of the AV associated with one or more changes to a software of the AV, the evaluation window comprising a time interval within a segment of the trip by the AV that includes the event encountered by the AV in the real-world environment;
iteratively adjusting the time interval associated with the evaluation window to yield a respective evaluation window determined in each iteration of adjustments to the time interval, each respective evaluation window comprising a respective time interval comprising a respective evaluation start, the event, and a respective evaluation end;
selecting a final evaluation window from the respective evaluation window determined in each iteration of adjustments to the time interval, the final evaluation window being selected based on a comparison of at least one of AV metrics calculated from each respective simulation of a pose and behavior of the AV during each respective evaluation window and divergences between the pose and behavior of the AV during each respective evaluation window and an additional pose and behavior of the AV during the trip by the AV in the real-world environment; and
simulating a respective pose and behavior of the AV during the final evaluation window.

12. The method of claim 11, wherein the final evaluation window is selected, from the respective simulation of the pose and behavior of the AV determined in each iteration of adjustments, based on a determination that the divergences between the pose and behavior of the AV during each respective evaluation window and the additional pose and behavior of the AV during the trip by the AV in the real-world environment are attributed to the one or more changes to the software of the AV.

13. The method of claim 11, wherein the final evaluation window is selected, from the respective simulation of the pose and behavior of the AV determined in each iteration of adjustments, based on a determination that a difference between one or more first AV metrics calculated from a respective simulation of the pose and behavior of the AV during the final evaluation window and one or more second AV metrics collected during the trip by the AV in the real-world environment relate to the event and the one or more changes to the software of the AV.

14. The method of claim 13, wherein the final evaluation window is selected further based on a determination that respective differences between AV metrics calculated from respective simulations of the pose and behavior of the AV during a set of evaluation windows and additional AV metrics collected during the trip by the AV in the real-world environment where caused by at least one of a different event, one or more portions of the software of the AV that are unrelated to one or more capabilities of the AV designed to handle the event, a non-repeatable feature of an AV software test involving the respective simulations, and a non-deterministic feature of the software of the AV, wherein the set of evaluation windows excludes the final evaluation window.

15. The method of claim 11, further comprising:
setting a first pose of the AV at a point prior to the respective evaluation window within each respective simulation to match a second pose of the AV at a corresponding point during the trip by the AV in the real-world environment; and
allowing a third pose of the AV during the respective evaluation window within each respective simulation to differ from a fourth pose of the AV at an additional corresponding point during the trip by the AV in the real-world environment.

16. The method of claim 11, wherein simulating the respective pose and behavior of the AV during the final evaluation window comprises collecting metrics associated with the AV while simulating the respective pose and behavior of the AV during the final evaluation window.

17. The method of claim 16, further comprising:
based on the metrics associated with the AV collected while simulating the respective pose and behavior of the AV during the final evaluation window, determining whether the one or more changes to the software of the AV correct at least one of an error and a failure experienced by the AV when at least one of encountering the event and responding to the event.

18. The method of claim 11, wherein the event comprises at least one of an error experienced by the AV, a failure experienced by the AV, and an incident encountered by the AV in which a response of the AV to the incident did not match an intended or expected response of the AV when encountering the incident.

19. The method of claim 11, further comprising:
determining a respective repeatability score for each respective simulation of the pose and behavior of the AV during each respective evaluation window; and
selecting the final evaluation window further based on the respective repeatability score for each respective simulation of the pose and behavior of the AV during each respective evaluation window.

20. A non-transitory computer-readable medium having stored thereon instructions which, when executed by one or more processors, cause the one or more processors to:
obtain, from one or more sensors of an autonomous vehicle (AV), sensor data collected by the one or more sensors during a trip by the AV in a real-world environment, wherein the sensor data reflects a pose and behavior of the AV implemented in response to an event encountered by the AV in the real-world environment;
generate, based on the sensor data, a simulation of the trip by the AV, the simulation comprising an evaluation window in which to test a simulated pose and behavior of the AV associated with one or more changes to a software of the AV, the evaluation window comprising a time interval within a segment of the trip by the AV that includes the event encountered by the AV in the real-world environment;
iteratively adjust the time interval associated with the evaluation window to yield a respective evaluation window determined in each iteration of adjustments to the time interval, each respective evaluation window comprising a respective time interval comprising a respective evaluation start, the event, and a respective evaluation end;
select a final evaluation window from the respective evaluation window determined in each iteration of adjustments to the time interval, the final evaluation window being selected based on a comparison of at least one of AV metrics calculated from each respective simulation of a pose and behavior of the AV during each respective evaluation window and divergences between the pose and behavior of the AV during each respective evaluation window and an additional pose and behavior of the AV during the trip by the AV in the real-world environment; and
simulate a respective pose and behavior of the AV during the final evaluation window.
